(19) United States
(12) Patent Application Publication
(10) Pub. No.: US 2026/0275038 A1
(43) Pub. Date: Sep. 17, 2026

(54) THERMOSETTING MALEIMIDE RESIN COMPOSITION, SHEET-LIKE OR FILM-LIKE COMPOSITION USING SAME, ADHESIVE AGENT COMPOSITION, PRIMER COMPOSITION, COMPOSITION FOR SUBSTRATES, COATING MATERIAL COMPOSITION, AND SEMICONDUCTOR DEVICE

(71) Applicant: NIPPON KAYAKU KABUSHIKI KAISHA, Tokyo (JP)

(72) Inventors: Kazuyoshi YAMAMOTO, Tokyo (JP); Mai TSUBAMOTO, Tokyo (JP); Mao TAKEDA, Tokyo (JP)

(73) Assignee: NIPPON KAYAKU KABUSHIKI KAISHA, Tokyo (JP)

(21) Appl. No.: 19/167,557

(22) PCT Filed: Mar. 18, 2024
(86) PCT No.: PCT/JP2024/010510

§ 371 Date: Sep. 22, 2025

(30) Foreign Application Priority Data
Mar. 23, 2023 (JP) 2023-046184

(51) Int. Cl. C08G 73/10; C09D 179/08; C09J 179/08

(52) U.S. Cl. CPC C08G 73/1085; C09D 179/08; C09J 179/08

(57) ABSTRACT

The purpose of the present invention is to provide a thermosetting maleimide resin composition that provides a cured product having a high glass transition temperature (Tg), excellent dielectric properties, and excellent adhesiveness with respect to metal foils, and that has fine compatibility and is cured uniformly without any post-curing nonuniformity. The thermosetting maleimide resin composition contains (I) a bismaleimide compound and (II) a reaction accelerator. The (I) bismaleimide compound has a cyclic imide bond obtained by reacting an aromatic diamine (A) represented by formula (1), a tetrabasic acid dianhydride (C), and maleic acid anhydride. In formula (1), each R₁ independently represents a hydrogen atom, a straight-chain or branched alkyl group having 1-6 carbon atoms, a halogen atom, a hydroxy group, or a straight-chain or branched alkoxy group having 1-6 carbon atoms. Each 1 independently represents an integer of 1-4.

### TECHNICAL FIELD

The present invention relates to a thermosetting maleimide resin composition, a sheet-like or film-like composition, an adhesive composition, a primer composition, a composition for substrates, a coating composition, and a semiconductor device using the same.

### BACKGROUND ART

In recent years, electronic devices have become smaller and more powerful, and there is a demand for finer and denser wiring in the surface protection films and interlayer insulating films of semiconductor elements, as well as the insulating films of redistribution layers. Furthermore, materials for high frequency bands will be required in the next generation, and the reduction of transmission loss will be essential as a noise countermeasure, so there is a demand for the development of insulating materials with excellent dielectric properties.

As insulating materials for multilayer printed wiring boards, epoxy resin compositions containing epoxy resin, a specific phenol-based curing agent, phenoxy resin, rubber particles, polyvinyl acetal resin, etc., as disclosed in Patent Literatures 1 and 2, are known, but it has become clear that these materials are not satisfactory for high-frequency band applications, such as those represented by the keyword 5G. In contrast, Patent Literature 3 reports that an epoxy resin composition containing an epoxy resin, an active ester compound, and a triazine-containing cresol novolac resin is effective in lowering the dielectric tangent, but even this material needs to have a lower dielectric constant for high-frequency band applications.

On the other hand, Patent Literature 4 reports that a resin film made of a resin composition containing a bismaleimide resin having a long-chain alkyl group as a non-epoxy material and a curing agent has excellent low dielectric properties. However, since this is essentially a combination of a bismaleimide resin having a long-chain alkyl group and a hard low-molecular aromatic maleimide, it has poor compatibility and is prone to uneven properties and curing, and it is very difficult to achieve a high glass transition temperature (Tg) of 100° C. or more required for substrate applications.

In addition, recent research has revealed that the aforementioned bismaleimide resins having long-chain alkyl groups have a trade-off relationship in resin design, in that increasing the Tg results in poorer dielectric properties, whereas improving the dielectric properties results in a lower Tg. It has also been found that increasing the Tg results in aggregation and separation of the resins, even between bismaleimide resins having the same long-chain alkyl groups, and thus reduces the compatibility of the resins.

Furthermore, Patent Literatures 5 and 6 disclose resin compositions containing polyimides made from aromatic tetracarboxylic anhydrides and dimer diamines or alicyclic diamines derived from dimer acids, which are dimers of unsaturated fatty acids such as oleic acid. However, the polyimides described in these documents are difficult to use in a single curing process, and are poorly compatible with other resins. In addition, since polyimides undergo ring-closing dehydration during curing, when a resin composition containing this polyimide is used by laminating it to a metal foil, for example, swelling is likely to occur depending on the conditions, which is not preferable.

In light of this background, polyphenylene ether resins (PPE) that can be thermoset by modifying the functional groups at the molecular chain ends have been used as the main resins for 5G substrates in recent years, as described in Patent Literatures 7 and 8. The cured product of modified PPE has a high Tg of 200° C. or higher, and is highly reliable.

### CITATION LIST

### Patent Literature

Patent Literature 1: Japanese Patent Publication No. 2007-254709A
Patent Literature 2: Japanese Patent Publication No. 2007-254710A
Patent Literature 3: Japanese Patent Publication No. 2011-132507A
Patent Literature 4: International Publication No. 2016/114287
Patent Literature 5: Japanese Patent Publication No. 2017-119361A
Patent Literature 6: Japanese Patent Publication No. 2019-104843A
Patent Literature 7: Japanese Patent Publication No. 2017-128718A
Patent Literature 8: Japanese Patent Publication No. 2018-95815A

### SUMMARY OF INVENTION

### Technical Problem

For 5G applications, it is preferable to use a metal foil with a small surface roughness, since the use of a metal foil with a rough surface increases transmission loss from the viewpoint of the skin effect. However, since the anchor effect cannot be obtained when a metal foil with a small surface roughness is used, a resin having higher adhesion to the metal foil is desired, but the modified PPE described in Patent Literature 7 and Patent Literature 8 has a problem with adhesion to the metal foil.

Therefore, the present invention aims to provide a thermosetting maleimide resin composition that has a high glass transition temperature (Tg) of the cured product, excellent dielectric properties, excellent adhesion to the metal foil, good compatibility with other resins, and cures uniformly without unevenness during curing. It is also an object of the present invention to provide an adhesive, a substrate material, a primer, a coating material, and a semiconductor device using the same.

Therefore, an object of the present invention is to provide a thermosetting maleimide resin composition which has good compatibility with other resins and can have a high Tg.

### Solution to Problem

The present inventors have conducted intensive research to solve the above problems and have found that the following thermosetting maleimide resin composition can achieve the above object, thereby completing the present invention.

That is, the present invention relates to the following items <1> to <18>.

<1> A thermosetting maleimide resin composition comprising:
(I) a bismaleimide compound; and
(II) a reaction accelerator,
   wherein the (I) bismaleimide compound is a bismaleimide compound having a cyclic imide bond and obtained by reacting: an aromatic diamine (A) represented by the following formula (1); a tetrabasic acid dianhydride (C); and maleic anhydride.

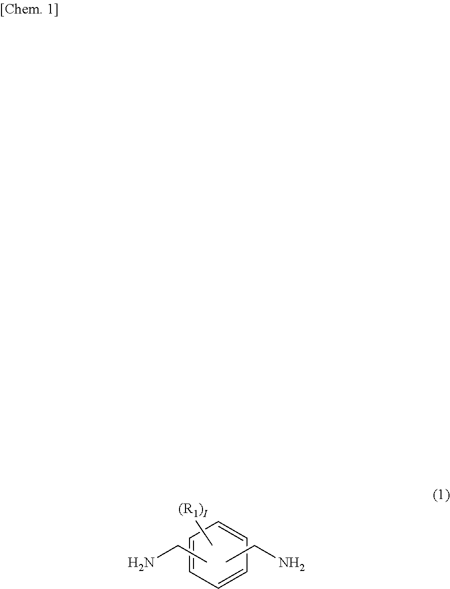

In formula (1), each R¹ independently represents a hydrogen atom, a linear or branched alkyl group having 1 to 6 carbon atoms, a halogen atom, a hydroxy group, or a linear or branched alkoxy group having 1 to 6 carbon atoms. Each 1 independently represents an integer from 1 to 4.

<2> The thermosetting maleimide resin composition according to <1>, further comprising:
(III) a thermosetting resin having, as a reactive group capable of reacting with a maleimide group, at least one group selected from: an epoxy group, a maleimide group, a hydroxy group, an acid anhydride group, an alkenyl group, a (meth)acrylic group, a thiol group, a cyano group, a phenol group, an oxetane group, a benzoxazine group, and a carbodiimide group.

<3> The thermosetting maleimide resin composition according to <1> or <2>, wherein the (I) bismaleimide compound is obtained by further reacting: a divalent organic diamine (B) having 6 to 200 carbon atoms other than the aromatic diamine (A), in addition to the aromatic diamine (A), the tetrabasic acid dianhydride (C), and the maleic anhydride.

<4> The thermosetting maleimide resin composition according to any one of <1> to <3>, wherein the bismaleimide compound (I) is represented by the following general formula (2).

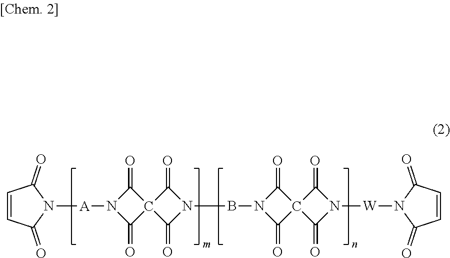

In formula (2), m is 1 to 100, and n is 0 to 100. The order of the repeating units bracketed by m and n is not limited, and the bonding pattern may be alternating, block, or random. C independently represents a tetravalent organic group containing a cyclic structure. W is A or B. B independently represents a divalent hydrocarbon group having 6 to 200 carbon atoms. A independently represents a divalent organic group represented by the following formula (3).

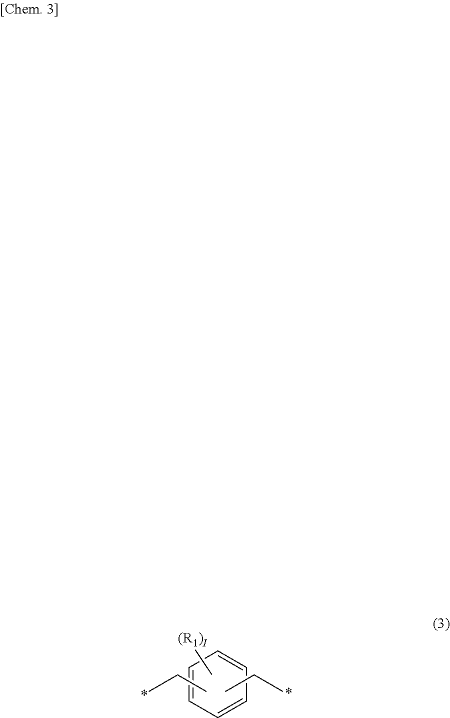

In formula (3), each R₁ independently represents a hydrogen atom, a linear or branched alkyl group having 1 to 6 carbon atoms, a halogen atom, a hydroxy group, or a linear or branched alkoxy group having 1 to 6 carbon atoms. Each 1 independently represents an integer of 1 to 4. * represents a linking portion with another moiety.

<5> The thermosetting maleimide resin composition according to any one of <1> to <4>, wherein the tetrabasic acid dianhydride (C) is selected from the group consisting of compounds represented by the following formulas (4) to (12).

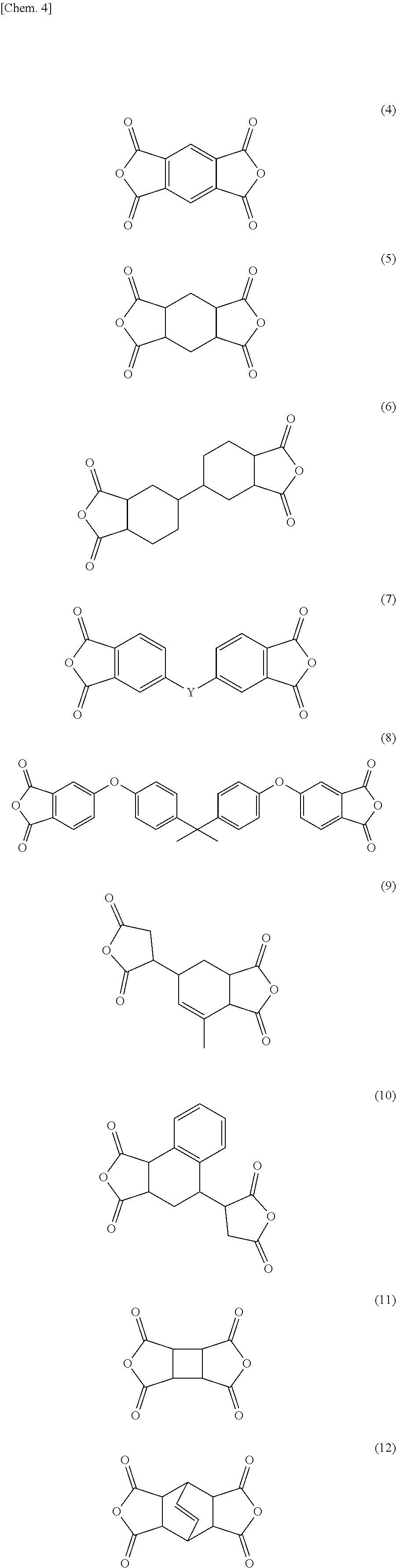

In formula (7), Y represents C(CF₃)₂, SO₂, CO, an oxygen atom, a direct bond, or a divalent linking group represented by the following formula (13).

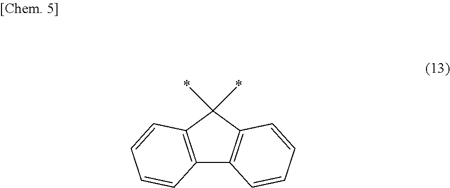

In the formula (13), * represents a linking portion to another moiety.

<6> The thermosetting maleimide resin composition according to any one of <1> to <5>, wherein the (I) bismaleimide compound is a maleimidized compound of an amine compound represented by the following formula (14).

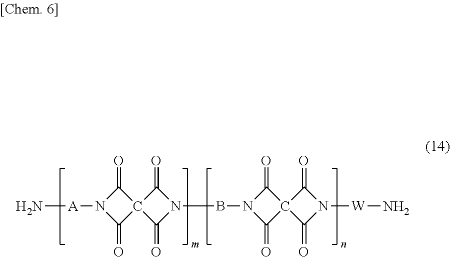

In formula (14), m is 1 to 100, and n is 0 to 100. The order of the repeating units bracketed by m and n is not limited, and the bonding pattern may be alternating, block, or random. C independently represents a tetravalent organic group containing a cyclic structure. W is A or B. B independently represents a divalent hydrocarbon group having 6 to 200 carbon atoms. A independently represents a divalent organic group represented by the following formula (3):

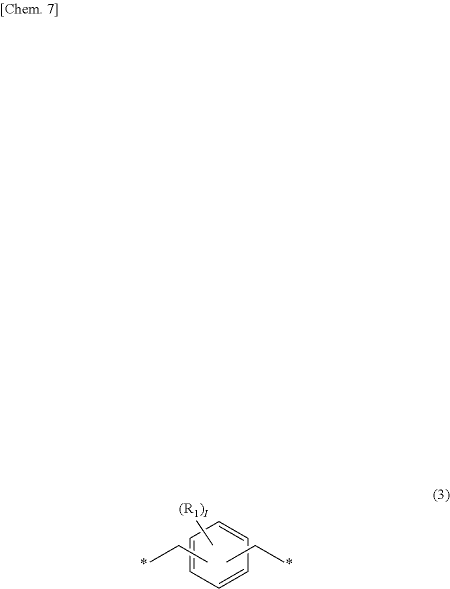

In formula (3), each R₁ independently represents a hydrogen atom, a linear or branched alkyl group having 1 to 6 carbon atoms, a halogen atom, a hydroxy group, or a linear or branched alkoxy group having 1 to 6 carbon atoms. Each 1 independently represents an integer of 1 to 4. * represents a linking portion with another moiety.

<7> The thermosetting maleimide resin composition according to any one of <1> to <6>, wherein the tetrabasic acid dianhydride (C) contains the bismaleimide compound (I) which is a compound represented by the following formula (15).

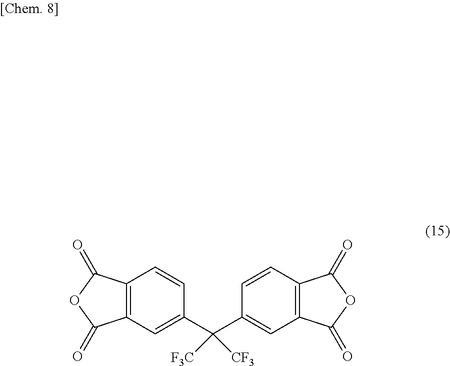 [SMILES: O=C1OC(=O)c2cc(C(c3ccc4c(c3)C(=O)OC4=O)(C(F)(F)F)C(F)(F)F)ccc21]

<8>

The thermosetting maleimide resin composition according to any one of <1> to <6>, wherein the tetrabasic acid dianhydride (C) contains a bismaleimide compound (I) which is a compound represented by the following formula (8).

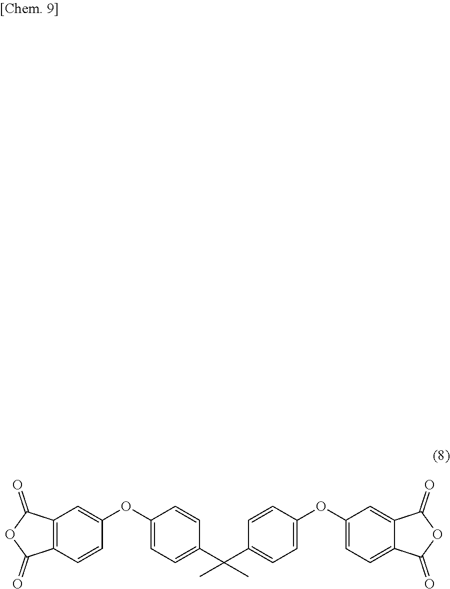 [SMILES: CC(C)(c1ccc(Oc2ccc3c(c2)C(=O)OC3=O)cc1)c1ccc(Oc2ccc3c(c2)C(=O)OC3=O)cc1]

The thermosetting maleimide resin composition according to any one of <1> to <6>, wherein the tetrabasic acid dianhydride (C) contains a bismaleimide compound (I) represented by the following formula (5).

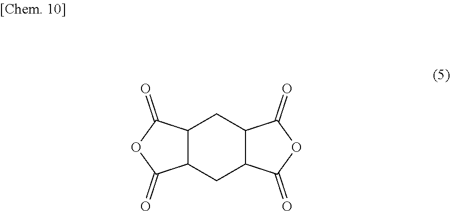 [SMILES: O=C1OC(=O)C2CC3C(=O)OC(=O)C3CC12]

<10>

The thermosetting maleimide resin composition according to any one of <1> to <6>, wherein the tetrabasic acid dianhydride (C) contains a bismaleimide compound (I) which is a compound represented by the following formula (9).

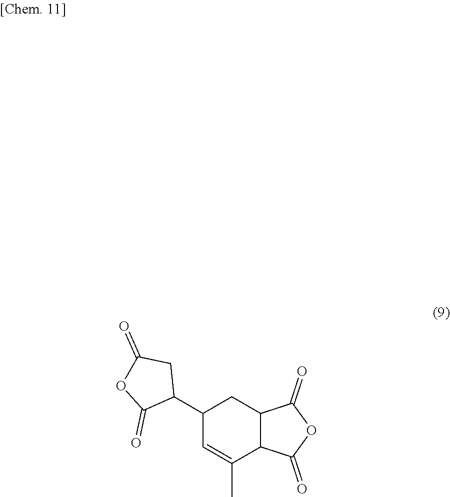 [SMILES: CC1=CC(C2CC(=O)OC2=O)CC2C(=O)OC(=O)C12]

<11>

The thermosetting maleimide resin composition according to any one of <1> to <6>, wherein the tetrabasic acid dianhydride (C) contains a bismaleimide compound (I) which is a compound represented by the following formula (10):

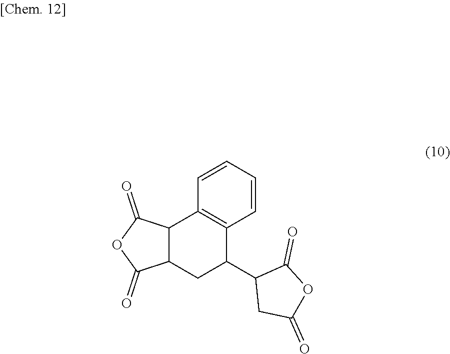 [SMILES: O=C1CC(C2CC3C(=O)OC(=O)C3c3ccccc32)C(=O)O1]

<12>

The thermosetting maleimide resin composition according to any one of <2> to <11>, wherein the (III) thermosetting resin having at least one group selected from epoxy group, maleimide group, hydroxy group, acid anhydride group, alkenyl group, (meth)acrylic group, thiol group, cyano group, phenol group, oxetane, benzoxazine, and carbodiimide as a reactive group capable of reacting with a maleimide group is at least one selected from the group consisting of maleimide compounds other than the bismaleimide compound (I), cyanate ester compounds, phenolic resins, epoxy resins, oxetane resins, benzoxazine compounds, carbodiimide compounds, and compounds having an ethylenically unsaturated group.

<13> A sheet-like or film-like composition comprising the thermosetting maleimide resin composition according to any one of <1> to <12>.

<14> An adhesive composition comprising the thermosetting maleimide resin composition according to any one of <1> to <12>.

<15> A primer composition comprising the thermosetting maleimide resin composition according to any one of <1> to <12>.

<16> A composition for a substrate, comprising the thermosetting maleimide resin composition according to any one of <1> to <12>.

<17> A coating composition comprising the thermosetting maleimide resin composition according to any one of <1> to <12>.

<18> A semiconductor device comprising a cured product of the thermosetting maleimide resin composition according to any one of <1> to <12>.

### Advantageous Effects of Invention

The thermosetting maleimide resin composition of the present invention has a high glass transition temperature of the cured product, excellent dielectric properties, and excellent adhesion to metal foil. In addition, the maleimide compound contained in the thermosetting maleimide resin composition of the present invention has excellent compatibility. In particular, since it has excellent compatibility with other resins having different structures, it is easy to use it in combination with other resins, and it is easy to complement each other's performance and bring out better performance. Furthermore, the thermosetting maleimide resin composition of the present invention can be cured uniformly without curing unevenness during curing, and in particular, when molded into a sheet, film, or substrate, there is little variation in curability and physical properties.

Therefore, the thermosetting maleimide resin composition of the present invention can be suitably used for adhesives, substrate materials, primers, coating materials, and semiconductor devices.

### DESCRIPTION OF EMBODIMENTS

The present invention relates to a thermosetting maleimide resin composition comprising (I) a bismaleimide compound and (II) a reaction accelerator.

The present invention will be described in detail below.

### < (I) Bismaleimide Compound>

The (I) bismaleimide compound (hereinafter also referred to as component (I)) is a compound having two maleimide groups, in which an acid anhydride forms a cyclic imide bond with an aromatic diamine. Such a (I) bismaleimide compound can be obtained by reacting an aromatic diamine (A) represented by the following formula (1), a tetrabasic acid dianhydride (C), and maleic anhydride.

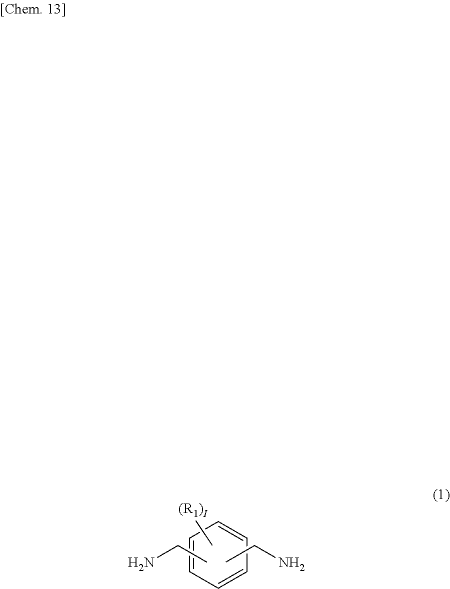

In formula (1), each R₁ independently represents a hydrogen atom, a linear or branched alkyl group having 1 to 6 carbon atoms, a halogen atom, a hydroxy group, or a linear or branched alkoxy group having 1 to 6 carbon atoms. Each 1 independently represents an integer of 1 to 4.

A divalent hydrocarbon group having 6 to 200 carbon atoms can be introduced into the bismaleimide compound by further reacting a divalent aliphatic diamine (B) having 6 to 200 carbon atoms other than the aromatic diamine (A), in addition to the aromatic diamine (A), the tetrabasic acid dianhydride (C), and the maleic anhydride, to form an imide bond.

The bismaleimide compound (I) is represented by the following general formula (2).

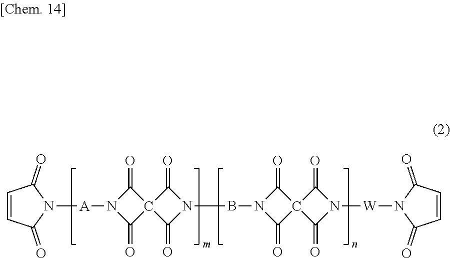

In formula (2), m is 0 to 100, and n is 1 to 100. The order of the repeating units bracketed by m and n is not limited, and the bonding pattern may be alternating, block, or random. C independently represents a tetravalent organic group containing a cyclic structure. W is A or B. B independently represents a divalent hydrocarbon group having 6 to 200 carbon atoms. A independently represents a divalent organic group represented by the following formula (3):

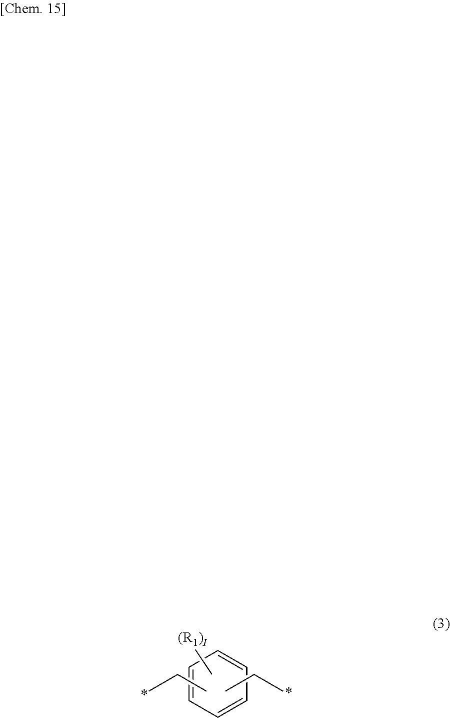

In formula (3), each R₁ independently represents a hydrogen atom, a linear or branched alkyl group having 1 to 6 carbon atoms, a halogen atom, a hydroxy group, or a linear or branched alkoxy group having 1 to 6 carbon atoms. Each 1 independently represents an integer of 1 to 4. * represents a linking portion to another moiety.

In the formula (1), each R₁ independently represents a hydrogen atom, a linear or branched alkyl group having 1 to 6 carbon atoms, a halogen atom, a hydroxy group, or a linear or branched alkoxy group having 1 to 6 carbon atoms.

The linear or branched alkyl group having 1 to 6 carbon atoms is not particularly limited, and examples thereof include methyl, ethyl, n-propyl, i-propyl, butyl, isobutyl, sec-butyl, and tert-butyl groups. Among these, alkyl groups having 1 to 4 carbon atoms are preferred, and methyl, ethyl, n-propyl, and i-propyl groups are more preferred, because they exhibit excellent adhesion to chips and substrates, as well as good solubility in solvents, low melting point, low water absorption, and good compatibility with other resins.

Examples of halogen atoms include fluorine, chlorine, bromine, and iodine atoms.

Examples of linear or branched alkoxy groups having 1 to 6 carbon atoms are not particularly limited, and examples thereof include methoxy, ethoxy, n-propoxy, iso-propoxy, n-butoxy, 2-methylpropoxy, 1-methylpropoxy, and tert-butoxy groups. Among these, alkoxy groups having 1 to 4 carbon atoms are preferred, and methoxy, ethoxy, n-propoxy, and iso-propoxy groups are more preferred, because they exhibit good solubility in solvents, low melting point, low water absorption, and good compatibility with other resins in addition to excellent adhesion to chips and substrates, etc.

As R₁, hydrogen atoms, methyl groups, ethyl groups, hydroxy groups, methoxy groups, and ethoxy groups are preferred, hydrogen atoms, methyl groups, and hydroxy groups are more preferred, and hydrogen atoms are even more preferred, because they exhibit good solubility in solvents, low melting point, low water absorption, and good compatibility with other resins in addition to excellent adhesion to chips and substrates, etc.

In the formula (1), each 1 independently represents an integer of 1 to 4. Since 1 exhibits excellent adhesion to chips, substrates, and the like, as well as good solubility in solvents, a low melting point, low water absorption, and good compatibility with other resins, it is preferable that all R₁ are hydrogen atoms, and therefore 1 is preferably 4.

Specific examples of the aromatic diamine (A) represented by the formula (1) include aromatic diamines such as metaxylenediamine (formula (17) below), paraxylenediamine (formula (18) below), and orthoxylenediamine (formula (19) below). As a commercially available product, metaxylenediamine (MXDA: manufactured by Mitsubishi Gas Chemical Company, Inc.) is easily available. As the aromatic diamine (A) represented by the formula (1), metaxylenediamine (formula (17) below) is preferred.

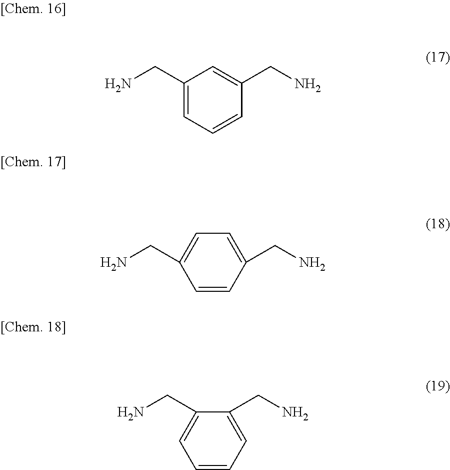 [SMILES: NCc1cccc(CN)c1 ; NCc1ccc(CN)cc1 ; NCc1ccccc1CN]

The bismaleimide compound (I) is not particularly limited as long as it exhibits the effects of the present invention, but from the viewpoints of good solubility in solvents, low melting point, low water absorbency, and good compatibility with other resins, the weight average molecular weight is preferably 100 to 100,000, and more preferably 500 to 30,000. In this embodiment, the “weight average molecular weight” means the weight average molecular weight calculated as a polystyrene standard by gel permeation chromatography (GPC).

Usually, maleimide compounds have poor light transmittance, so when a resin composition contains a maleimide compound other than the (I) bismaleimide compound, light does not reach the photocuring initiator dispersed in the resin composition sufficiently, and the photocuring initiator does not generate radicals easily. Therefore, the photoradical reaction of the maleimide compound generally does not proceed easily, and even if radical polymerization or dimerization reaction of the maleimide alone proceeds, the reactivity of the photoradical reaction of the maleimide compound is very low. However, the maleimide compound according to the present embodiment has very excellent light transmittance because the maleimide group is bonded to the aromatic ring via the methylene group and has a short conjugation length, so that light reaches the photocuring initiator sufficiently and the photoradical reaction of the maleimide occurs efficiently. When a chloroform solution containing the maleimide compound at 1% by mass is prepared and the light transmittance of this chloroform solution is measured using light of a wavelength of 405 nm (h-line), the transmittance is 3% or more, which is very excellent light transmittance. Therefore, for example, when a printed wiring board having a high-density and high-definition wiring formation (pattern) is produced by using a direct imaging exposure method, a photoradical reaction of maleimide occurs efficiently even when active energy rays having a wavelength of 405 nm (h-rays) are used.

When using active energy rays including a wavelength of 405 nm (h-rays), polymerization will not proceed unless the photocuring initiator absorbs light of a wavelength of 405 nm (h-rays) and generates radicals. Therefore, in this case, it is preferable to use a photocuring initiator that has an absorbance of 0.1 or more at a wavelength of 405 nm (h-rays) and exhibits very excellent absorbency for light of a wavelength of 405 nm (h-rays) as the photocuring initiator described below.

Since the maleimide compound of this embodiment has excellent light transmittance as described above, even when light having a wavelength of 405 nm is used, the light sufficiently reaches the photocuring initiator, a radical reaction using radicals generated from the photocuring initiator proceeds, and photocuring is possible even in a resin composition containing a large amount of the maleimide compound.

Furthermore, a cured product obtained by containing the resin composition of this embodiment has excellent photocurability, heat resistance, and thermal stability, and can be suitably used to form a protective film and an insulating layer.

In the formula (2), B is independently a divalent hydrocarbon group having 6 to 200 carbon atoms, preferably 8 to 100 carbon atoms, more preferably 10 to 50 carbon atoms. Among them, it is preferable that the divalent hydrocarbon group is a branched divalent hydrocarbon group in which one or more hydrogen atoms in the divalent hydrocarbon group are substituted with an alkyl group or an alkenyl group having 6 to 200 carbon atoms, preferably 8 to 100 carbon atoms, more preferably 10 to 50 carbon atoms. The branched divalent hydrocarbon group may be either a saturated aliphatic hydrocarbon group or an unsaturated hydrocarbon group, and may have an alicyclic structure or an aromatic ring structure in the middle of the molecular chain. Specific examples of the branched divalent hydrocarbon group include a hydrocarbon group derived from so called “dimer diamine”, which has amino groups at both ends. Note that dimer diamine is a compound in which two carboxyl groups of a dimer acid, a dimer of unsaturated fatty acids such as oleic acid, are substituted with primary amino groups, as shown in the following formulas (20) to (25) (see JP 9-12712 A, etc.). Specific examples of commercially available dimer diamines include PRIAMINE (registered trademark) 1074 and PRIAMINE (registered trademark) 1075 (both manufactured by Croda Japan Co., Ltd.), and Versamine 551 (manufactured by Cognis Japan Co., Ltd.). These may be used alone or in combination of two or more. Non-limiting general formulas of dimer diamines are shown below. In each formula, m+n is preferably 6 to 17, p+q is preferably 8 to 19, and the dashed line represents a carbon-carbon single bond or a carbon-carbon double bond.

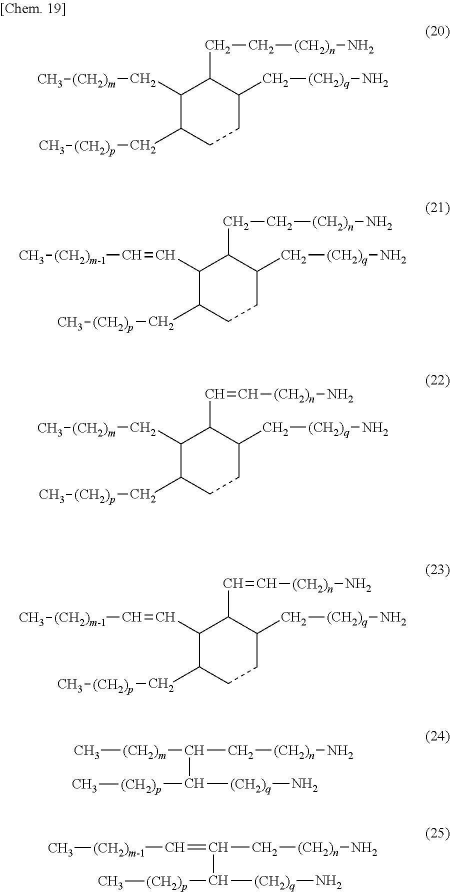

The tetrabasic acid dianhydride (C) used in the synthesis of the bismaleimide compound (I) is not particularly limited as long as it has two acid anhydride groups in one molecule. Specific examples of the component (C) include pyromellitic anhydride, ethylene glycol bis(anhydrotrimellitate), glycerin bis(anhydrotrimellitate) monoacetate, 1,2,3,4-butane tetracarboxylic acid dianhydride, 3,3′,4,4′-diphenylsulfone tetracarboxylic acid dianhydride, 3,3′,4,4′-benzophenone tetracarboxylic acid dianhydride, 3,3′,4,4′-biphenyl tetracarboxylic acid dianhydride, 3,3′,4,4′-diphenyl ether tetracarboxylic acid dianhydride, 5-(2,5-dioxotetrahydro-3-furanyl)-3-methylcyclohexene-1,2-dicarboxylic acid anhydride, 3a,4,5,9b-tetrahydro-5-(tetrahydro-2,5-dioxo-3-furanyl)-naphtho[1,2-c]furan-1,3-dione, 1,2,4,5-cyclohexanetetracarboxylic dianhydride, bicyclo(2,2,2)-oct-7-ene-2,3,5,6-tetracarboxylic dianhydride and bicyclo[2.2.2]octane-2,3,5,6-tetracarboxylic dianhydride, 5,5′-((propane-2,2-diylbis(4,1-phenylene))bis(oxy))bis(isobenzofuran-1,3-dione), 4,4′-oxydiphthalic anhydride, 4,4′-(hexafluoroisopropylidene)diphthalic anhydride, and 4,4′-bisphenol A acid dianhydride. Among these, 4,4′-oxydiphthalic anhydride, 4,4′-(hexafluoroisopropylidene)diphthalic anhydride, and 4,4′-bisphenol A acid dianhydride are preferred from the viewpoints of solvent solubility and adhesion to a substrate. These may be used alone or in combination of two or more.

The tetrabasic acid dianhydride (C) used in the synthesis of the bismaleimide compound (I) is preferably selected from the group consisting of compounds represented by the following formulas (4) to (12), from the viewpoint of the solvent solubility of the finally obtained bismaleimide resin.

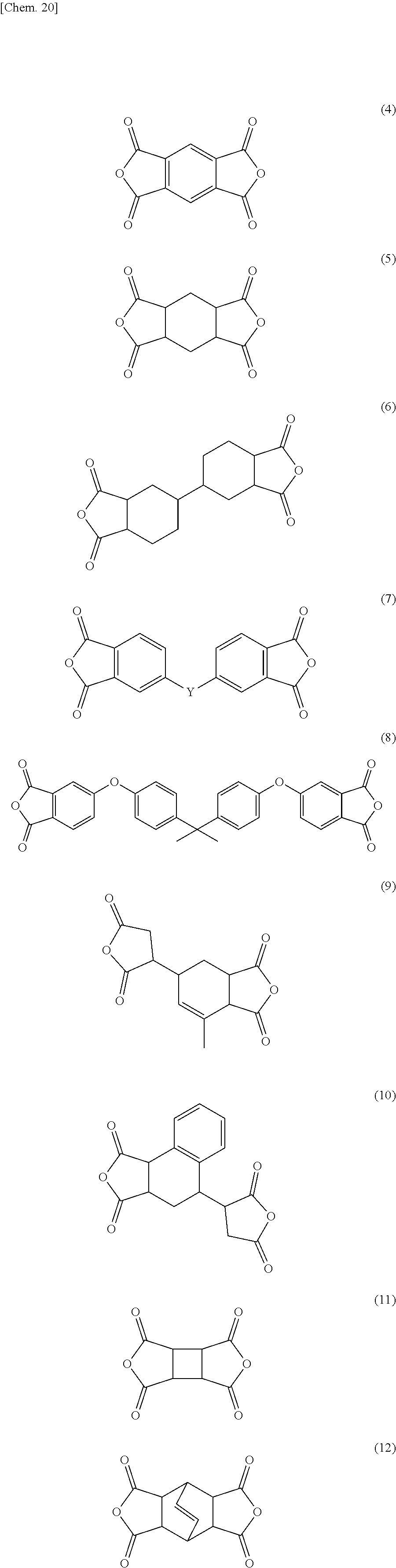

In formula (7), Y represents C(CF₃)₂, SO₂, CO, an oxygen atom, a direct bond, or a divalent linking group represented by the following formula (13).

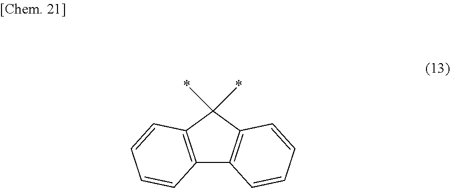

In formula (13), * indicates a linkage to other moieties.

In the bismaleimide compound (I), the tetrabasic acid dianhydride (C) is preferably a tetrabasic acid dianhydride (C) represented by the following general formula (15).

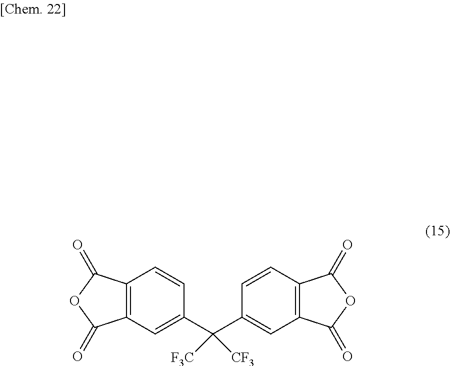

In the bismaleimide compound (I), the tetrabasic acid dianhydride (C) is preferably a tetrabasic acid dianhydride (C) represented by the following general formula (8).

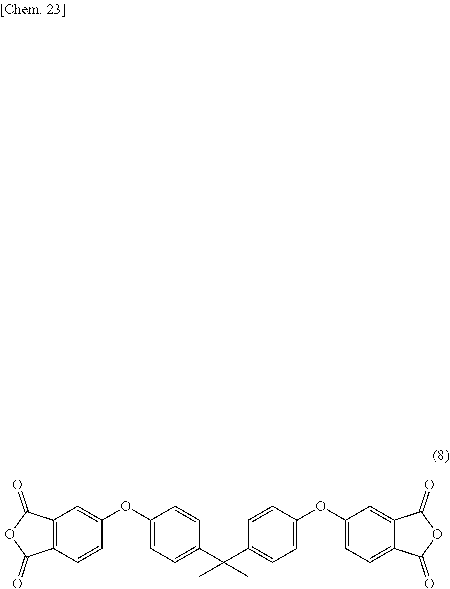

In the bismaleimide compound (I), the tetrabasic acid dianhydride (C) is preferably a tetrabasic acid dianhydride (C) represented by the following general formula (5).

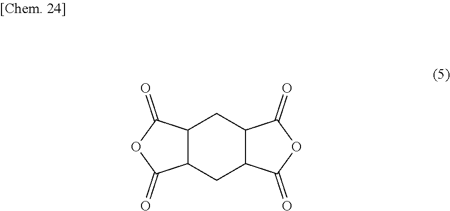

In the bismaleimide compound (I), the tetrabasic acid dianhydride (C) is preferably a tetrabasic acid dianhydride (C) represented by the following general formula (9).

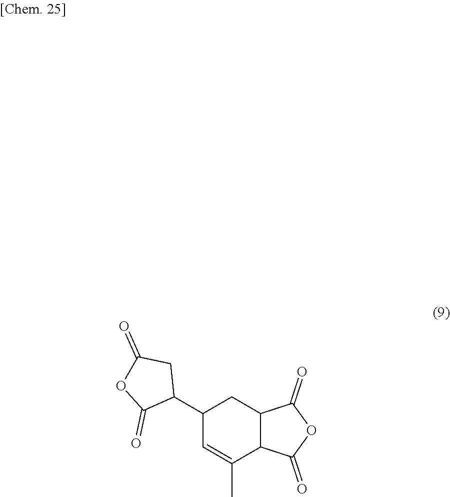

In the bismaleimide compound (I), the tetrabasic acid dianhydride (C) is preferably a tetrabasic acid dianhydride (C) represented by the following general formula (10).

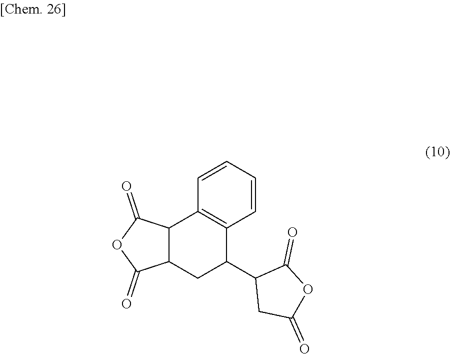

Furthermore, the (I) bismaleimide compound may be a bismaleimide compound obtained by reacting the aromatic diamine (A), an organic diamine (B) other than the aromatic diamine (A), the tetrabasic acid dianhydride (C), and the maleic anhydride. By copolymerizing the organic diamine (B) other than the aromatic diamine (A), it becomes possible to control the required physical properties as needed, such as further improving the heat resistance of the obtained cured product.

In the present invention, the organic diamine (B) other than the aromatic diamine (A) (hereinafter sometimes simply referred to as organic diamine (B)) refers to a diamine other than the diamine contained in the aromatic diamine (A). Such organic diamine (B) is not particularly limited, and examples thereof include: aliphatic diamines such as 1,6-hexanediamine; alicyclic diamines such as 1,4-diaminocyclohexane, 1,3-bis(aminomethyl)cyclohexane, isophoronediamine, and norbornenediamine; aromatic diamines such as 4,4′-diaminodiphenyl ether, 3,4′-diaminodiphenyl ether, 1,4-bis(4-aminophenoxy)benzene, 1,3-bis(aminomethyl)benzene, 1,3-bis(4-aminophenoxy)benzene, 1,4-diaminobenzene, 2,4-diaminotoluene, 4,4′-diaminodiphenylmethane; 4,4′-diaminodiphenylsulfone; 3,3′-diaminodiphenylsulfone; 4,4-diaminobenzophenone; 4,4-diaminodiphenylsulfide; and 2,2-bis[4-(4-aminophenoxy)phenyl]propane. Among these, from the viewpoint of obtaining a cured product having high heat resistance, aliphatic diamines having 6 to 12 carbon atoms such as 1,6-hexamethylenediamine; and diaminocyclohexanes such as 1,3-bis(aminomethyl)cyclohexane, isophoronediamine, and norbornenediamine, are more preferred. In addition, when obtaining the bismaleimide compound (I) using these organic diamines (B), one of these organic diamines (B) may be used alone or two or more of them may be used in combination.

The bismaleimide compound (I), particularly the bismaleimide compound (I) having an aromatic ring skeleton, has excellent compatibility with resins having different structures, and is therefore easily used in combination with other resins, and it is easy to complement each other's performance and bring out better performance. Furthermore, the bismaleimide compound of the present invention, particularly the bismaleimide compound having an aromatic ring skeleton, can provide a bismaleimide resin composition that, when molded into a film or substrate, has little variation in curability and physical properties and gives a cured product having a high glass transition point (Tg).

### Method for Producing the Bismaleimide Compound (I)

The method for producing the bismaleimide compound (I) is not particularly limited, but the compound can be produced efficiently by the method shown below, for example.

The basic flow is to synthesize an amic acid from a tetrabasic acid dianhydride and a diamine, and then undergo ring-closing dehydration in step A, react with maleic anhydride to synthesize a maleamic acid, and finally undergo ring-closing dehydration to cap the molecular chain terminals with maleimide groups in step B, thereby obtaining the bismaleimide compound (I).

In the above-mentioned production method, each step can be roughly divided into two steps: a synthesis reaction of an amic acid or a maleamic acid, and a ring-closing dehydration reaction, which will be described in detail below.

In step A, a specific tetrabasic acid dianhydride is reacted with a specific diamine to synthesize an amic acid. This reaction generally proceeds in an organic solvent (e.g., a non-polar solvent or a high-boiling aprotic polar solvent) at room temperature (25° C.) to 100° C.

The subsequent ring-closing dehydration reaction of the amic acid is carried out under conditions of 90 to 120° C., while the water by-produced by the condensation reaction is removed from the system. In order to promote the ring-closing dehydration reaction, an organic solvent (e.g., a non-polar solvent, a high-boiling aprotic polar solvent, etc.) or an acid catalyst can be added.

Examples of the organic solvent include toluene, xylene, anisole, biphenyl, naphthalene, N,N-dimethylformamide (DMF), and dimethyl sulfoxide (DMSO). These may be used alone or in combination of two or more.

Examples of the acid catalyst include sulfuric acid, methanesulfonic acid, and trifluoromethanesulfonic acid. These may be used alone or in combination of two or more.

The molar ratio of the diamine to the tetrabasic acid dianhydride is preferably diamine/tetrabasic acid dianhydrate=2.5 to 1.02/1.0, and more preferably diamine/tetrabasic acid dianhydride=2.0 to 1.15/1.0. By blending at this ratio, a copolymer having amino groups at both ends can be synthesized.

As the copolymer having amino groups at both ends, an amine compound represented by the following formula (14) can be used.

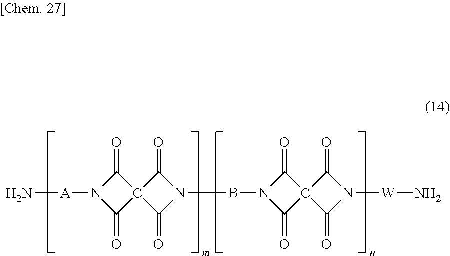

In formula (14), m is 1 to 100, and n is 0 to 100. The order of the repeating units bracketed by m and n is not limited, and the bonding pattern may be alternating, block, or random. C independently represents a tetravalent organic group containing a cyclic structure. W is A or B. B independently represents a divalent hydrocarbon group having 6 to 200 carbon atoms. A independently represents a divalent organic group represented by the following formula (3).

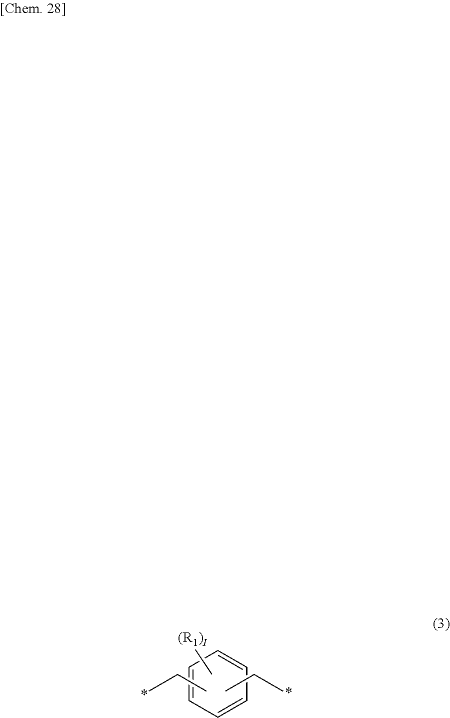

In formula (3), R₁ independently represents a hydrogen atom, a linear or branched alkyl group having 1 to 6 carbon atoms, a halogen atom, a hydroxy group, or a linear or branched alkoxy group having 1 to 6 carbon atoms. Each 1 independently represents an integer of 1 to 4. * represents a linking portion with another portion.

That is, the (I) bismaleimide compound is preferably a maleimide of an amine compound represented by the above formula (14).

In step B, the copolymer having amino groups at both ends obtained in step A is reacted with maleic anhydride at room temperature (25° C.) to 100° C. to synthesize maleamic acid, and finally, the molecular chain ends are blocked with maleimide groups by ring-closing dehydration while removing water by-produced in the system under conditions of 95 to 120° C., thereby obtaining the desired bismaleimide compound. It is preferable to carry out the blocking reaction with maleimide groups at the molecular chain ends at 120° C. or less, since side reactions and high molecular weight compounds are less likely to occur.

With such a production method, the obtained bismaleimide compound has a block copolymer structure, and therefore the compatibility of the synthesized resin with other resins can be made uniform and improved.

The compound of the present invention may be purified by a conventional method, such as reprecipitation.

In the present invention, the bismaleimide compound component (I) is preferably 1 to 99% by mass, and more preferably 5 to 95% by mass, of the resin solid content.

### (II) Reaction Accelerator

The reaction accelerator (II) (hereinafter also referred to as component (II)) is added to accelerate the crosslinking reaction of the maleimide compound (I) or the reaction between the maleimide group in component (I) and a reactive group capable of reacting with the maleimide group in component (III) described below.

There are no particular limitations on the component (II) as long as it accelerates the crosslinking reaction, and examples of the component (II) include ionic catalysts such as imidazoles, tertiary amines, quaternary ammonium salts, boron trifluoride amine complexes, organophosphines, and organophosphonium salts, organic peroxides such as diallyl peroxide, dialkyl peroxide, peroxide carbonate, and hydroperoxide, and radical polymerization initiators such as azoisobutyronitrile. Examples of imidazoles include 2-methylimidazole, 2-ethylimidazole, 2-phenylimidazole, 2-ethyl-4-methylimidazole, 2-undecylimidazole, and 1-cyanoethyl-2-ethyl-4-methylimidazole. Examples of amines include triethylamine, triethylenediamine, 2-(dimethylaminomethyl)phenol, 1,8-diaza-bicyclo(5,4,0) undecene-7, tris(dimethylaminomethyl)phenol, and benzyldimethylamine. Examples of phosphines include triphenylphosphine, tributylphosphine, and trioctylphosphine. Among these, organic peroxides and radical polymerization initiators are preferred when component (I) is reacted alone or when the reactive group in component (III) is a carbon-carbon double bond such as a maleimide group, an alkenyl group, and a (meth)acrylic group; or basic compounds such as imidazoles and tertiary amines are preferred when the reactive group in component (III) is an epoxy group, a hydroxy group, or an acid anhydride group.

The reaction accelerator (II) is preferably blended in an amount of 0.05 to 10 parts by mass, particularly 0.1 to 5 parts by mass, per 100 parts by mass of the total of the thermosetting resin components such as the components (I) and (III). If the amount is outside the above range, the maleimide resin composition may be cured very slowly or quickly during molding, which is not preferable. In addition, the balance between the heat resistance and moisture resistance of the resulting cured product may be poor.

(III) Thermosetting Resin Having a Reactive Group Capable of Reacting with a Maleimide Group (Hereinafter Also Referred to as Component (III))

The thermosetting maleimide resin composition may further include a thermosetting resin having a reactive group capable of reacting with a maleimide group as component (III).

Examples of reactive groups capable of reacting with a maleimide group include epoxy groups, maleimide groups, hydroxy groups, acid anhydride groups, alkenyl groups such as allyl groups and vinyl groups, (meth)acrylic groups, thiol groups, cyano groups, phenol groups, oxetane, benzoxazine, and carbodiimide. However, among the thermosetting resins having a maleimide group as a reactive group, those corresponding to the maleimide compound of component (I) are excluded from component (III). From the viewpoint of reactivity, the reactive group of the thermosetting resin, which is component (III), is preferably selected from among epoxy groups, maleimide groups, hydroxy groups, acid anhydride groups, and alkenyl groups, and furthermore, from the viewpoint of dielectric properties, an alkenyl group or a (meth)acrylic group is more preferable.

The number average molecular weight of the thermosetting resin of component (III) is preferably 350 to 6,000, and more preferably 1,000 to 5,000.

The component (III) may be used alone or in combination of two or more kinds. The component (III) is preferably blended in an amount of 5 to 90% by mass, and more preferably 15 to 85% by mass, based on 100% by mass of the resin component.

The composition containing the bismaleimide compound (I) above preferably contains a thermosetting resin having a reactive group capable of reacting with a maleimide group.

The thermosetting resin having a reactive group capable of reacting with a maleimide group may include (I) one or more selected from the group consisting of maleimide compounds other than bismaleimide compounds (hereinafter also referred to as “other maleimide compounds”), cyanate ester compounds, phenolic resins, epoxy resins, oxetane resins, benzoxazine compounds, carbodiimide compounds, and compounds having an ethylenically unsaturated group. Each component of the thermosetting resin having a reactive group capable of reacting with a maleimide group will be described below.

((I) Maleimide Compounds Other than Bismaleimide Compounds)

The other maleimide compounds are not particularly limited as long as they are other than the maleimide compound (I) of the present embodiment and have one or more maleimide groups in the molecule. Specific examples thereof include: N-phenylmaleimide, N-cyclohexylmaleimide, N-hydroxyphenylmaleimide, N-anilinophenylmaleimide, N-carboxyphenylmaleimide, N-(4-carboxy-3-hydroxyphenyl) maleimide, 6-maleimidohexanoic acid, 4-maleimidobutyric acid, bis(4-maleimidophenyl) methane, 2,2-bis {4-(4-maleimidophenoxy)-phenyl}propane, 4,4-diphenylmethane bismaleimide, bis(3,5-dimethyl-4-maleimidophenyl) methane, bis(3-ethyl-5-methyl-4-maleimidophenyl) methane, bis(3,5-diethyl-4-maleimidophenyl) methane, phenylmethane maleimide, o-phenylene bismaleimide, m-phenylene bismaleimide, p-phenylene bismaleimide, o-phenylene biscitraconimide, m-phenylene biscitraconimide, p-phenylene biscitraconimide, 2,2-bis(4-(4-maleimidophenoxy)-phenyl) propane, 3,3-dimethyl-5,5-diethyl-4,4-diphenylmethane bismaleimide, 4-methyl-1,3-phenylene bismaleimide, 1,2-bismaleimide ethane, 1,4-bismaleimide butane, 1,5-bismaleimide pentane, 1,5-bismaleimido-2-methylpentane, 1,6-bismaleimidohexane, 1,6-bismaleimido-(2,2,4-trimethyl) hexane, 1,8-bismaleimido-3,6-dioxaoctane, 1,11-bismaleimido-3,6,9-trioxaundecane, 1,3-bis(maleimidomethyl)cyclohexane, 1,4-bis(maleimidomethyl)cyclohexane, 4,4-diphenyletherbismaleimide, 4,4-diphenylsulfonebismaleimide, 1,3-bis(3-maleimidophenoxy)benzene, 1,3-bis(4-maleimidophenoxy)benzene, 4,4-diphenylmethanebis citraconimide, 2,2-bis[4-(4-citraconimidophenoxy)phenyl]propane, bis(3,5-dimethyl-4-citraconimidophenyl) methane, bis(3-ethyl-5-methyl-4-citraconimidophenyl) methane, bis(3,5-diethyl-4-citraconimidophenyl) methane, maleimide compounds represented by formula (26) such as polyphenylmethanemaleimide; maleimide compounds represented by formulas (27) or (28), fluorescein-5-maleimide, and prepolymers of these maleimide compounds, or prepolymers of maleimide compounds and amine compounds. These maleimide compounds can be used alone or in appropriate mixtures of two or more.

As the other maleimide compound represented by formula (26), commercially available products may be used, for example, BMI-2300 (trade name) manufactured by Daiwa Kasei Kogyo Co., Ltd. As the other maleimide compound represented by formula (27), commercially available products may be used, for example, MIR-3000 (trade name) manufactured by Nippon Kayaku Co., Ltd. As the other maleimide compound represented by formula (28), commercially available products may be used, for example, MIR-5000 (trade name) manufactured by Nippon Kayaku Co., Ltd.

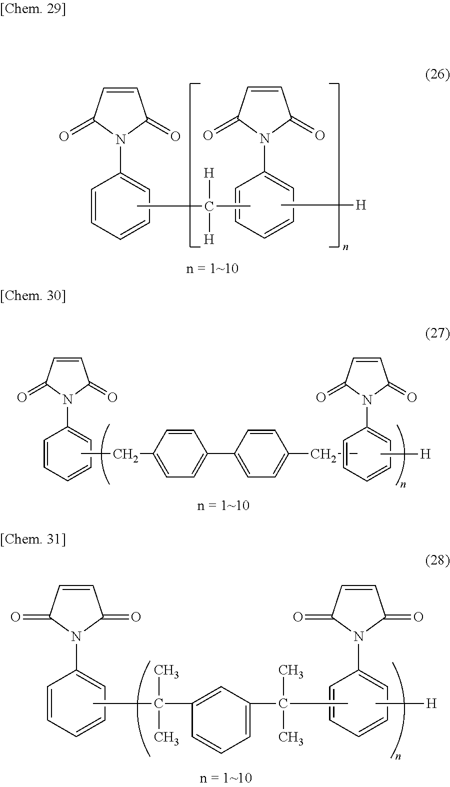

In the composition according to the present embodiment, the total content of the other maleimide compounds is not particularly limited, but is preferably 0.01 to 50 parts by mass per 100 parts by mass of the resin solid content in the composition according to the present embodiment.

### (Cyanate Ester Compound)

The cyanate ester compound is a cyanate ester compound obtained by reacting a phenolic resin with a cyanogen halide. Specific examples thereof include dicyanatobenzene, tricyanatobenzene, dicyanatonaphthalene, dicyanatobiphenyl, 2,2′-bis(4-cyanatophenyl)propane, bis(4-cyanatophenyl)methane, bis(3,5-dimethyl-4-cyanatophenyl)methane, 2,2′-bis(3,5-dimethyl-4-cyanatophenyl)propane, 2,2′-bis(4-cyanatophenyl)ethane, 2,2′-bis(4-cyanatophenyl)hexafluoropropane, bis(4-cyanatophenyl)sulfone, bis(4-cyanatophenyl)thioether, phenol novolacyanate, and phenol-dicyclopentadiene co-condensates in which the hydroxy groups have been converted to cyanate groups, but are not limited thereto.

Furthermore, the cyanate ester compound, the synthesis method of which is described in JP-A-2005-264154, is particularly preferred as the cyanate ester compound, since it has low moisture absorption, flame retardancy, and excellent dielectric properties.

The cyanate ester compound may contain a catalyst such as zinc naphthenate, cobalt naphthenate, copper naphthenate, lead naphthenate, zinc octylate, tin octylate, lead acetylacetonate, or dibutyltin maleate, in order to trimerize the cyanate group to form a sym-triazine ring, if necessary. The catalyst is used in an amount of usually 0.0001 to 0.10 parts by mass, preferably 0.00015 to 0.0015 parts by mass, per 100 parts by mass of the total mass of the composition.

In the composition according to the present embodiment, the total content of the cyanate ester compounds is not particularly limited, but is preferably 0.01 to 50 parts by mass per 100 parts by mass of the resin solid content in the composition according to the present embodiment.

### (Phenolic Resin)

As the phenolic resin, as long as it is a phenolic resin having two or more hydroxy groups in one molecule, generally known ones can be used. For example, bisphenol A type phenolic resin, bisphenol E type phenolic resin, bisphenol F type phenolic resin, bisphenol S type phenolic resin, phenol novolac resin, bisphenol A novolac type phenolic resin, glycidyl ester type phenolic resin, aralkyl novolac type phenolic resin, biphenyl aralkyl type phenolic resin, cresol novolac type phenolic resin, multifunctional phenolic resin, naphthol resin, naphthol novolac resin, multifunctional naphthol resin, anthracene type phenolic resin, naphthalene skeleton modified novolac type phenolic resin, phenol aralkyl type phenolic resin, naphthol aralkyl type phenolic resin, dicyclopentadiene type phenolic resin, biphenyl type phenolic resin, alicyclic phenolic resin, polyol type phenolic resin, phosphorus-containing phenolic resin, polymerizable unsaturated hydrocarbon group-containing phenolic resin, and hydroxy group-containing silicone resin can be mentioned, but not particularly limited. These phenolic resins may be used alone or in a suitable mixture of two or more kinds.

In the composition according to the present embodiment, the total content of the phenolic resin is not particularly limited, but is preferably 0.01 to 50 parts by mass per 100 parts by mass of the resin solid content in the composition according to the present embodiment.

### (Epoxy Resin)

The epoxy resin is not particularly limited, and generally known epoxy resins can be used. For example, bisphenol A type epoxy resins, bisphenol E type epoxy resins, bisphenol F type epoxy resins, bisphenol S type epoxy resins, bisphenol A novolac type epoxy resins, biphenyl type epoxy resins, phenol novolac type epoxy resins, cresol novolac type epoxy resins, xylene novolac type epoxy resins, multifunctional phenol type epoxy resins, naphthalene type epoxy resins, naphthalene skeleton modified novolac type epoxy resins, naphthylene ether type epoxy resins, phenol aralkyl type epoxy resins, anthracene type epoxy resins, trifunctional phenol type epoxy resins, tetrafunctional phenol type epoxy resins, triglycidyl isocyanurate, glycidyl ester type epoxy resins, alicyclic epoxy resins, dicyclopentadiene novolac type epoxy resins, biphenyl novolac type epoxy resins, phenol aralkyl novolac type epoxy resins, naphthol aralkyl novolac type epoxy resins, aralkyl novolac type epoxy resins, naphthol aralkyl type epoxy resins, dicyclopentadiene type epoxy resins, polyol type epoxy resins, phosphorus-containing epoxy resins, glycidylamine, compounds in which the double bonds of butadiene, etc. are epoxidized, compounds obtained by reacting hydroxy group-containing silicone resins with epichlorohydrin, and halides thereof. These epoxy resins can be used alone or in a suitable mixture of two or more.

In the composition according to the present embodiment, the total content of the epoxy resin is not particularly limited, but is preferably 0.01 to 50 parts by mass per 100 parts by mass of the resin solid content in the composition according to the present embodiment.

### (Oxetane Resin)

As the oxetane resin, generally known ones can be used. For example, alkyl oxetanes such as oxetane, 2-methyl oxetane, 2,2-dimethyl oxetane, 3-methyl oxetane, and 3,3-dimethyl oxetane, 3-methyl-3-methoxymethyl oxetane, 3,3-di(trifluoromethyl)perfluorooxetane, 2-chloromethyl oxetane, 3,3-bis(chloromethyl)oxetane, biphenyl oxetane, OXT-101 (manufactured by Toagosei Co., Ltd., trade name), and OXT-121 (manufactured by Toagosei Co., Ltd., trade name) can be mentioned, but are not particularly limited. These oxetane resins can be used alone or in a suitable mixture of two or more kinds.

In the composition according to this embodiment, the total content of the oxetane resin is not particularly limited, but is preferably 0.01 to 40 parts by mass per 100 parts by mass of the resin solid content in the composition according to this embodiment.

### (Benzoxazine Compound)

As the benzoxazine compound, generally known compounds can be used as long as they have two or more dihydrobenzoxazine rings in one molecule. For example, bisphenol A benzoxazine BA-BXZ (manufactured by Konishi Chemical Co., Ltd., trade name), bisphenol F benzoxazine BF-BXZ (manufactured by Konishi Chemical Co., Ltd., trade name), bisphenol S benzoxazine BS-BXZ (manufactured by Konishi Chemical Co., Ltd., trade name), phenolphthalein benzoxazine, etc. can be mentioned, but are not particularly limited. These benzoxazine compounds can be used alone or in appropriate mixture of two or more kinds.

In the composition according to the present embodiment, the total content of the benzoxazine compounds is not particularly limited, but is preferably 0.01 to 40 parts by mass per 100 parts by mass of the resin solid content in the composition according to the present embodiment.

### (Carbodiimide Compound)

The carbodiimide compound is not particularly limited as long as it has at least one carbodiimide group in the molecule, and generally known compounds can be used. For example, dicyclohexylcarbodiimide, diisopropylcarbodiimide, dimethylcarbodiimide, diisobutylcarbodiimide, dioctylcarbodiimide, t-butylisopropylcarbodiimide, diphenylcarbodiimide, di-t-butylcarbodiimide, di-β-naphthylcarbodiimide, N,N′-di-2,6-diisopropylphenylcarbodiimide, 2,6,2′,6′-tetraisopropyldiphenylcarbodiimide, cyclic carbodiimide, Carbodilite (registered trademark: manufactured by Nisshinbo Chemical Inc.), and Stavaxol (registered trademark: manufactured by LANXESS Deutschland GmbH) and other polycarbodiimides can be mentioned. These carbodiimide compounds can be used alone or in a suitable mixture of two or more kinds.

In the composition according to the present embodiment, the total content of the carbodiimide compounds is not particularly limited, but is preferably 0.01 to 40 parts by mass per 100 parts by mass of the resin solid content in the composition according to the present embodiment.

### (Compound Having an Ethylenically Unsaturated Group)

The compound having an ethylenically unsaturated group is not particularly limited as long as it has an ethylenically unsaturated group in one molecule.

Specific examples of compounds having an ethylenically unsaturated group include methyl (meth)acrylate, ethyl (meth)acrylate, butyl (meth)acrylate, lauryl (meth)acrylate, polyethylene glycol (meth)acrylate, polyethylene glycol (meth)acrylate monomethyl ether, phenylethyl (meth)acrylate, isobornyl (meth)acrylate, cyclohexyl (meth)acrylate, benzyl (meth)acrylate, tetrahydrofurfuryl (meth)acrylate, butanediol di(meth)acrylate, hexanediol di(meth)acrylate, neopentyl glycol di(meth)acrylate, nonanediol di(meth)acrylate, glycol di(meth)acrylate, diethylene di(meth)acrylate, polyethylene glycol di(meth)acrylate, tris(meth)acryloyloxyethyl isocyanurate, and polypropylene glycol di(meth)acrylate, adipic acid epoxy di(meth)acrylate, bisphenol ethylene oxide di(meth)acrylate, hydrogenated bisphenol ethylene oxide (meth)acrylate, bisphenol di(meth)acrylate, ε-caprolactone modified hydroxypivalic acid neopen glycol di(meth)acrylate, ε-caprolactone modified dipentaerythritol hexa(meth)acrylate, ε-caprolactone modified dipentaerythritol poly(meth)acrylate, dipentaerythritol poly(meth)acrylate, trimethylolpropane tri(meth)acrylate, triethylolpropane tri(meth)acrylate, and ethylene oxide adducts thereof; pentaerythritol tri(meth)acrylate, and ethylene oxide adducts thereof; pentaerythritol tetra(meth)acrylate, dipentaerythritol hexa(meth)acrylate, and ethylene oxide adducts thereof.

Other specific examples of the compound having an ethylenically unsaturated group include: urethane (meth)acrylates having both a (meth)acryloyl group and a urethane bond in the same molecule; polyester (meth)acrylates having both a (meth)acryloyl group and an ester bond in the same molecule; epoxy (meth)acrylates derived from epoxy resins and also having a (meth)acryloyl group; and reactive oligomers in which these bonds are used in combination.

Examples of urethane (meth)acrylates include reaction products of hydroxy group-containing (meth)acrylate with polyisocyanate and other alcohols used as necessary. Examples of urethane (meth)acrylates include hydroxyalkyl (meth)acrylates such as hydroxyethyl (meth)acrylate, hydroxypropyl (meth)acrylate, and hydroxybutyl (meth)acrylate; glycerin (meth)acrylates such as glycerin mono(meth)acrylate and glycerin di(meth)acrylate; urethane (meth)acrylates obtained by reacting sugar alcohol (meth)acrylates such as pentaerythritol di(meth)acrylate, pentaerythritol tri(meth)acrylate, dipentaerythritol penta(meth)acrylate, dipentaerythritol hexa(meth)acrylate, with polyisocyanates such as toluene diisocyanate, hexamethylene diisocyanate, trimethylhexamethylene diisocyanate, isophorone diisocyanate, norbornene diisocyanate, xylene diisocyanate, hydrogenated xylene diisocyanate, dicyclohexanemethylene diisocyanate, and their isocyanurates and biuret reaction products.

Examples of polyester (meth)acrylates include monofunctional (poly)ester (meth)acrylates such as caprolactone-modified 2-hydroxyethyl (meth)acrylate, ethylene oxide and/or propylene oxide-modified phthalic acid (meth)acrylate, ethylene oxide-modified succinic acid (meth)acrylate, and caprolactone-modified tetrahydrofurfuryl (meth)acrylate; di(poly) ester (meth)acrylates such as hydroxypivalic acid ester neopentyl glycol di(meth)acrylate, caprolactone-modified hydroxypivalic acid ester neopentyl glycol di(meth)acrylate, and epichlorohydrin-modified phthalic acid di(meth)acrylate; and mono-, di-, or tri(meth)acrylates of triols obtained by adding 1 mole or more of a cyclic lactone compound such as ε-caprolactone, γ-butyrolactone, or δ-valerolactone to 1 mole of trimethylolpropane or glycerin.

Further examples include mono-, di-, tri-, or tetra(meth)acrylates of triols obtained by adding 1 mole or more of a cyclic lactone compound such as ε-caprolactone, γ-butyrolactone, δ-valerolactone, etc. to 1 mole of pentaerythritol, dimethylolpropane, trimethylolpropane, or tetramethylolpropane; mono- or poly(meth)acrylates of triols obtained by adding 1 mole or more of a cyclic lactone compound such as ε-caprolactone, γ-butyrolactone, δ-valerolactone, etc. to 1 mole of dipentaerythritol, or mono(meth)acrylates or poly(meth)acrylates of polyhydric alcohols such as triols, tetraols, pentaols, or hexaols.

Further examples include: polyfunctional (poly)ester (meth)acrylates such as (meth)acrylates of polyester polyols which are reaction products of diol components such as (poly)ethylene glycol, (poly)propylene glycol, (poly)tetramethylene glycol, (poly)butylene glycol, 3-methyl-1,5-pentanediol, and hexanediol, with polybasic acids such as maleic acid, fumaric acid, succinic acid, adipic acid, phthalic acid, isophthalic acid, hexahydrophthalic acid, tetrahydrophthalic acid, dimer acid, sebacic acid, azelaic acid, and 5-sodium sulfoisophthalic acid, and anhydrides thereof; and polyfunctional (poly)ester (meth)acrylates such as (meth)acrylates of the diol components, the polybasic acids or the anhydrides thereof and cyclic lactone-modified polyester diols consisting of εs-caprolactone, γ-butyrolactone, δ-valerolactone, and the like.

Epoxy (meth)acrylates are carboxylate compounds of compounds having epoxy groups and (meth)acrylic acid. Examples of epoxy (meth)acrylates include phenol novolac epoxy (meth)acrylates, cresol novolac epoxy (meth)acrylates, trishydroxyphenylmethane epoxy (meth)acrylates, dicyclopentadienephenol epoxy (meth)acrylates, bisphenol A epoxy (meth)acrylates, bisphenol F epoxy (meth)acrylates, biphenol epoxy (meth)acrylates, bisphenol A novolac epoxy (meth)acrylates, naphthalene skeleton-containing epoxy (meth)acrylates, glyoxal epoxy (meth)acrylates, heterocyclic epoxy (meth)acrylates, and their acid anhydride-modified epoxy acrylates.

Specific examples of the compound having an ethylenically unsaturated group include vinyl ethers such as ethyl vinyl ether, propyl vinyl ether, hydroxyethyl vinyl ether, and ethylene glycol divinyl ether; styrenes such as styrene, methylstyrene, ethylstyrene, and divinylbenzene; and compounds having a vinyl group such as triallyl isocyanurate, trimethallyl isocyanurate, and bisallylnadimide.

As the compound having an ethylenically unsaturated group, commercially available products can be used, and examples thereof include KAYARAD (registered trademark) ZXR-801H (trade name, manufactured by Nippon Kayaku Co., Ltd.), and propylene glycol monomethyl ether acetate of dicyclopentadiene type epoxy acrylate compound (KAYARAD (registered trademark) ZXR-1806H (trade name), KAYARAD (registered trademark) ZXR-1810H (trade name), and KAYARAD (registered trademark) ZXR-1889H (trade name), manufactured by Nippon Kayaku Co., Ltd.). These compounds having an ethylenically unsaturated group can be used alone or in appropriate mixture of two or more types.

In the composition according to the present embodiment, the total content of the compounds having an ethylenically unsaturated group is not particularly limited, but is preferably 0.01 to 60 parts by mass per 100 parts by mass of the resin solid content in the composition according to the present embodiment.

The composition contains components other than the compound represented by the general formula (2). Examples of other components contained in the resin composition include organic solvents, photopolymerization initiators, curing agents having reactive groups capable of reacting with maleimide groups, and adhesion enhancers such as curing catalysts or coupling agents, and fillers. Various other components can be used without particular limitation according to the application and method of use of the resin composition. Resin compositions containing organic solvents are preferred because they are easy to handle.

In addition, the bismaleimide compound (I) can be used without using photopolymerization initiators, curing agents, curing catalysts, etc. because it is capable of self-polymerization reaction.

### (Photopolymerization Initiator)

The bismaleimide compound represented by the general formula (2) can self-polymerize by itself, but it can also be self-polymerized after forming a composition by using a photopolymerization initiator or a curing catalyst in combination with the compound represented by the general formula (2). By using a photopolymerization initiator in combination, it becomes possible to self-polymerize by irradiation with light, and by using a curing catalyst in combination, it is possible to lower the heating temperature during self-polymerization compared to when no curing catalyst is used.

The photopolymerization initiator that can be used in combination with the self-polymerization is not particularly limited, and any conventionally used initiator can be appropriately used. Specific examples of the photopolymerization initiator include acetophenone, 2,2-dimethoxyacetophenone, p-dimethylaminoacetophenone, Michler's ketone, benzil, benzoin, benzoin methyl ether, benzoin ethyl ether, benzoin isopropyl ether, benzoin n-propyl ether, benzoin isopropyl ether, benzoin n-butyl ether, benzyl dimethyl ketal, thioxanthone, 2-chlorothioxanthone, 2-methylthioxanthone, 2,2-dimethoxy-1,2-diphenylethane-1-one, 1-hydroxy-cyclohexyl-phenyl-ketone, 2-hydroxy-2-methyl-1-phenyl-propan-1-one, 1-[4-(2-hydroxyethoxy)-phenyl]-2-hydroxy-2-methyl-1-propan-1-one, 2-hydroxy-1-{4-[4-(2-hydroxy-2-methyl-propionyl)-benzyl]phenyl}-2-methyl-propan-1-one, 2-methyl-1-[4-(methylthio)phenyl]-2-morpholinopropan-1-one, 2-benzyl-2-dimethylamino-1-(4-morpholinophenyl)-1-butanone, 2,4,6-trimethylbenzoyl-diphenyl-phosphine oxide, bis(2,4,6-trimethylbenzoyl)-phenylphosphine oxide, 1-[4-(phenylthio)phenyl]-1,2-octanedione=2-(O-benzoyloxime), 1-[9-ethyl-6-(2-methylbenzoyl)-9H-carbazol-3-yl]ethanone 1-(O-acetyloxime), and 2,4-dimethylthioxanthone. These photopolymerization initiators may be used alone or in combination of two or more.

Among these, from the viewpoint of enabling fine pattern formation using a reduction projection exposure machine (stepper; light source wavelength: 365 nm, 436 nm) that is standardly used in the manufacturing process of semiconductor protective films and the like, it is preferable to use one that efficiently generates radicals at an exposure wavelength of 310 to 436 nm (more preferably 365 nm). Preferred examples of the photopolymerization initiator include 1-[4-(phenylthio)phenyl]-1,2-octanedione-2-(O-benzoyloxime) (manufactured by BASF Japan, “IRGACURE OXE-01”), 1-[9-ethyl-6-(2-methylbenzoyl)-9H-carbazol-3-yl]ethanone 1-(O-acetyloxime) (manufactured by BASF Japan, “IRGACURE OXE-02”), 2,4-dimethylthioxanthone (manufactured by Nippon Kayaku Co., Ltd., “DETX-S”), and 2-methyl-1-[4-(methylthio)phenyl]-2-morpholinopropan-1-one (manufactured by IGM Resins B.V., “Omirad 907”).

The amount of the photopolymerization initiator used is preferably 0.1 to 20 parts by mass, more preferably 1 to 5 parts by mass, based on 100 parts by mass of the compound represented by formula (1).

A sensitizer may be used in combination with the photopolymerization initiator. The sensitizer that can be used in combination is not particularly limited as long as it is a conventionally known sensitizer, and examples thereof include 4,4′-bis(diethylamino)benzophenone.

The amount of the sensitizer used is preferably 2 parts by mass or less, more preferably 0.05 to 0.5 parts by mass, based on 100 parts by mass of the compound represented by formula (2). By using a sensitizer in combination, the sensitivity to light during self-polymerization can be increased.

### (Curing Catalyst)

The curing catalyst that can be used in combination during self-polymerization is not particularly limited as long as it can promote the self-polymerization of the maleimide groups at both ends of the compound represented by formula (1) by heating, and conventionally used catalysts can be appropriately adopted. Specific examples of the curing catalyst include imidazoles such as 2-methylimidazole, 2-ethylimidazole, 2-phenylimidazole, 2-ethyl-4-methylimidazole, 2-undecylimidazole, and 1-cyanoethyl-2-ethyl-4-methylimidazole; amines such as triethylamine, triethylenediamine, 2-(dimethylaminomethyl)phenol, 1,8-diaza-bicyclo(5,4,0)undecene-7, tris(dimethylaminomethyl)phenol, and benzyldimethylamine; phosphines such as triphenylphosphine, tributylphosphine, and trioctylphosphine; organometallic salts such as tin octylate, zinc octylate, dibutyltin dimaleate, zinc naphthenate, cobalt naphthenate, and tin oleate, metal chlorides such as zinc chloride, aluminum chloride, and tin chloride, organic peroxides such as di-tert-butyl peroxide and dicumyl peroxide, azo compounds such as azobisisobutyronitrile and azobisdimethylvaleronitrile, mineral acids such as hydrochloric acid, sulfuric acid, and phosphoric acid, Lewis acids such as boron trifluoride, and salts such as sodium carbonate and lithium chloride.

The amount of the curing catalyst used is preferably 10 parts by mass or less, more preferably 1 to 5 parts by mass, based on 100 parts by mass of the compound represented by formula (1).

The curing agent is not particularly limited, and a conventionally used compound can be appropriately adopted. The curing agent is not particularly limited as long as it is a compound having a functional group (or structure) capable of crosslinking with a maleimide compound, such as an amino group, a cyanate group, a phenolic hydroxy group, or an alcoholic hydroxy group. In addition, a maleimide compound other than the (I) bismaleimide compound may be used in combination.

### (Organic Solvent)

The organic solvent is not particularly limited, but examples thereof include γ-butyrolactone, ethyl lactate, propylene glycol monomethyl ether acetate, benzyl acetate, n-butyl acetate, ethoxyethyl propionate, 3-methylmethoxypropionate, N-methyl-2-pyrrolidone, N-ethyl-2-pyrrolidone, N,N-dimethylformamide, N,N-dimethylacetamide, dimethylsulfoxide, hexamethylphosphorylamide, tetramethylene sulfone, cyclohexanone, cyclopentanone, diethyl ketone, diisobutyl ketone, and methyl amyl ketone. These organic solvents can be used alone or in combination of two or more. The use of an organic solvent in combination is a preferred embodiment in terms of improving the handling of the composition.

There is no particular limit to the content of the organic solvent in the composition of the present invention, but the content of the solvent in the composition is usually 95% by mass or less, preferably 20 to 90% by mass.

### (Silane Coupling Agent)

Examples of the silane coupling agent include, but are not limited to, 3-chloropropyltrimethoxysilane, vinyltrichlorosilane, vinyltriethoxysilane, vinyltrimethoxysilane, vinyl-tris(2-methoxyethoxy)silane, 3-methacryloxypropyltrimethoxysilane, 2-(3,4-epoxycyclohexyl)ethyltrimethoxysilane, 3-glycidoxypropyltrimethoxysilane, 3-mercaptopropyltrimethoxysilane, 3-aminopropyltriethoxysilane, N-2-(aminoethyl)-3-aminopropyltrimethoxysilane, and 3-ureidopropyltriethoxysilane. These can be used alone or in combination of two or more.

Since the silane coupling agent is unreactive with the compound of the present invention (compound, self-polymerizing compound, benzoxazole), components other than those acting at the substrate interface may remain as residual components after curing. Therefore, the use of a large amount of the agent may have adverse effects such as a decrease in physical properties. Depending on the type of substrate, even a small amount can be effective, so it is appropriate to use it within a range that does not have a negative effect. The proportion of the agent used is usually 15% by mass or less, and preferably more than 0% by mass and 5% by mass or less, based on the composition, but the upper limit of the proportion may vary depending on the type of substrate.

### (Thermoplastic Resin, Etc.)

Examples of the thermoplastic resin include polyethersulfone, polystyrene, polycarbonate, etc. Examples of the colorant include phthalocyanine blue, phthalocyanine green, iodine green, crystal violet, titanium oxide, carbon black, naphthalene black, etc. Examples of the thickener include orben, bentone, montmorillonite, etc. Examples of the thermal polymerization inhibitor include hydroquinone, 2,6-di-tert-butyl-p-methylphenol, etc. Examples of the defoamer include silicone-based, fluorine-based, and polymer-based defoamers.

The amount of these additives used in the composition of the present invention is preferably 30% by mass or less, for example, as a rough guideline, but may be increased or decreased as appropriate depending on the purpose of use.

### (Filler)

The resin composition of the present embodiment may further contain a filler in order to improve various properties such as coating properties, heat resistance, etc. The filler is preferably one that has insulating properties and does not inhibit the transparency to light with a wavelength of 405 nm (h-line). The filler is not particularly limited, but examples thereof include silica (e.g., natural silica, fused silica, amorphous silica, hollow silica, etc.), aluminum compounds (e.g., boehmite, aluminum hydroxide, alumina, aluminum nitride, etc.), boron compounds (e.g., boron nitride, etc.), magnesium compounds (e.g., magnesium oxide, magnesium hydroxide, etc.), calcium compounds (e.g., calcium carbonate, etc.), molybdenum compounds (e.g., molybdenum oxide, zinc molybdate, etc.), barium compounds (e.g., barium sulfate, barium silicate, etc.), talc (e.g., natural talc, calcined talc, etc.), mica, glass (e.g., short fiber glass, spherical glass, fine powder glass (e.g., E glass, T glass, D glass, etc.), etc.), silicone powder, fluororesin-based fillers, urethane resin-based fillers, (meth)acrylic resin-based fillers, polyethylene-based fillers, styrene-butadiene rubber, and silicone rubber. These fillers can be used alone or in a suitable mixture of two or more.

Among these, it is preferable to use one or more selected from the group consisting of silica, boehmite, barium sulfate, silicone powder, fluororesin-based fillers, urethane resin-based fillers, (meth)acrylic resin-based fillers, polyethylene-based fillers, styrene-butadiene rubber, and silicone rubber.

These fillers may be surface-treated with a silane coupling agent or the like, which will be described later.

From the viewpoints of improving the heat resistance of the cured product obtained by curing the resin composition of this embodiment and obtaining good coating properties, silica is preferred, and fused silica is more preferred. Specific examples of silica include SFP-130MC manufactured by Denka Co., Ltd., and SC2050-MB, SC1050-MLE, YA010C-MFN, and YA050C-MJA manufactured by Admatechs Co., Ltd.

The particle size of the filler is not particularly limited, but is usually 0.005 to 100 μm, and preferably 0.01 to 50 μm.

In the resin composition of the present embodiment, the content of the filler is not particularly limited, but from the viewpoint of improving the heat resistance of the cured product, it is preferably 1000 parts by mass or less, more preferably 500 parts by mass or less, and most preferably 300 parts by mass or less, relative to 100 parts by mass of the resin solid content in the resin composition. In addition, when a filler is contained, the lower limit is not particularly limited, but from the viewpoint of obtaining an effect of improving various properties such as coating property and heat resistance, it is usually 1 part by mass relative to 100 parts by mass of the resin solid content in the resin composition.

### <Other Additives>

The thermosetting maleimide resin composition of the present invention may further contain various additives as necessary within the scope of not impairing the effects of the present invention. Examples of such additives include organopolysiloxanes having reactive functional groups, non-functional silicone oils, thermoplastic resins, thermoplastic elastomers, organic synthetic rubbers, photosensitizers, light stabilizers, polymerization inhibitors, flame retardants, pigments, dyes, adhesive aids, etc. In order to improve the electrical properties of the cured product of the thermosetting maleimide resin composition, an ion trapping agent or the like may also be added as other additives.

The thermosetting maleimide resin composition of the present invention can be dissolved in an organic solvent and treated as a varnish. The thermosetting maleimide resin composition can be easily molded into a sheet or film by forming it into a varnish, and can also be easily applied to and impregnated into glass cloth made of E-glass, low dielectric glass, quartz glass, or the like. Any organic solvent can be used without limitation as long as it dissolves the thermosetting resin components of the components (I) and (III). Suitable organic solvents include, for example, toluene, xylene, anisole, cyclohexanone, and cyclopentanone.

The above organic solvents may be used alone or in combination of two or more. The concentration of the thermosetting maleimide resin composition of the present invention in the varnish is preferably 5 to 80% by mass, more preferably 10 to 75% by mass.

This thermosetting maleimide resin composition can be used as an adhesive, a primer, a coating material for semiconductor devices and the like, and further as a material for substrates. There are no limitations on the method or form of use. Examples of use are given below, but the present invention is not limited thereto.

For example, a thermosetting maleimide resin composition (varnish) dissolved in an organic solvent is applied to a substrate, and then the organic solvent is removed by heating for 0.5 to 5 hours at a temperature of usually 80° C. or higher, preferably 100° C. or higher, and then further heating for 0.5 to 10 hours at a temperature of 150° C. or higher, preferably 175° C. or higher, to form a maleimide resin cured coating having a flat surface and a strong surface. The temperatures in the drying step for removing the organic solvent and the subsequent heat curing step may each be constant, but it is preferable to increase the temperature in a stepwise manner. This allows the organic solvent to be efficiently removed from the composition and allows the curing reaction of the resin to proceed efficiently.

The cured film obtained by curing the thermosetting maleimide resin composition of the present invention is excellent in heat resistance, mechanical properties, electrical properties, adhesion to substrates, and solvent resistance, and also has a low dielectric constant. Therefore, it can be applied to, for example, semiconductor devices, specifically, passivation films and protective films on the surface of semiconductor elements, junction protective films for junctions of diodes, transistors, etc., alpha-ray shielding films for VLSIs, interlayer insulating films, ion implantation masks, etc., as well as conformal coats for printed circuit boards, alignment films for liquid crystal surface elements, protective films for glass fibers, and surface protective films for solar cells. Furthermore, it can be applied to a wide range of paste compositions, such as a printing paste composition when an inorganic filler is blended with the thermosetting maleimide resin composition of the present invention, and a conductive paste composition when a conductive filler is blended with the thermosetting maleimide resin composition of the present invention.

Methods for applying the thermosetting maleimide resin composition dissolved in an organic solvent to a substrate include, but are not limited to, a spin coater, a slit coater, a spray, a dip coater, a bar coater, and the like.

Furthermore, by molding the epoxy resin molding material for semiconductor encapsulation after forming the cured film, the adhesion between the epoxy resin molding material for semiconductor encapsulation and the substrate can be improved. The semiconductor device obtained in this manner is highly reliable, since no cracks are observed on the epoxy resin molding material for semiconductor encapsulation and no peeling from the substrate are observed during solder reflow after moisture absorption.

In this case, as the epoxy resin molding material for semiconductor encapsulation, a known epoxy resin composition for semiconductor encapsulation containing an epoxy resin having two or more epoxy groups in one molecule, a phenolic resin, an epoxy resin curing agent such as an acid anhydride, and an inorganic filler, etc., can be used, and a commercially available product can also be used.

In this case, when the substrate is made of a metal that is easily oxidized, such as copper, the environment in which the thermosetting maleimide resin composition or the epoxy resin molding material for semiconductor encapsulation of the present invention is fully cured is preferably a nitrogen atmosphere to prevent oxidation.

Alternatively, the resin composition of the present invention may be applied to a support sheet in the form of a film for use. As the support sheet, a commonly used one may be used, for example, polyolefin resins such as polyethylene (PE) resin, polypropylene (PP) resin, and polystyrene (PS) resin, and polyester resins such as polyethylene terephthalate (PET) resin, polybutylene terephthalate (PBT) resin, and polycarbonate (PC) resin, and the surface of these support sheets may be subjected to a release treatment. In addition, the coating method is not particularly limited, and examples thereof include a gap coater, a curtain coater, a roll coater, and a laminator. In addition, the thickness of the coating layer is not particularly limited, but the thickness after distillation of the solvent is in the range of 1 to 100 μm, preferably 3 to 80 μm. Furthermore, a cover film may be used on the coating layer.

Moreover, a copper foil can be attached onto the coating layer to form a copper foil with resin, which can be used as a substrate material.

In addition, the varnished resin composition can be impregnated into glass cloth made of E-glass, low dielectric glass, quartz glass, or the like, and the organic solvent can be removed to form a B-stage, allowing it to be used as a prepreg.

### EXAMPLES

The present invention will be described in more detail below based on examples and comparative examples, but the present invention is not limited to the following examples. In the examples, “parts” and “%” are based on mass.

The molecular weight measurement conditions are as follows:
Model: GPC TOSOH HLC-8220 GPC
column: Super HZM-N
Eluent: THF (tetrahydrofuran); 0.35 ml/min, 40° C.
Detector: RI (refractive index detector)
Molecular weight standard: polystyrene

### Synthesis Example 1 (I-1)

162 g of toluene and 162 g of N-methylpyrrolidone were charged to a 1 L round bottom flask equipped with a thermometer, reflux condenser, Dean-Stark apparatus, powder inlet, nitrogen inlet, and stirrer. 32.4 g (0.24 mol) of metaxylenediamine (Mitsubishi Gas Chemical Co., Ltd.) was then added, followed by the slow addition of 22.9 g (0.24 mol) of methanesulfonic acid to form the salt. The mixture was stirred for approximately 10 minutes to mix, and then 52.8 g (0.12 mol) of 4,4′-(hexafluoroisopropylidene)diphthalic anhydride was slowly added to the stirred mixture. The mixture was heated to reflux for 6 hours to form the amine-terminated diimide. The water produced from this condensation reached the theoretical amount by this time. The reaction mixture was cooled to below room temperature, and 28.0 g (0.29 mol) of maleic anhydride was added to the flask. The mixture was refluxed for an additional 8 hours, yielding the expected amount of water. After cooling to room temperature, the organic layer was washed with water (100 ml×5 times) to remove salts and unreacted raw materials, yielding a varnish of the bismaleimide compound. The varnish was then dropped into 1,000 g of methanol to carry out a reprecipitation step, and the solvent was removed and dried to obtain 78 g (yield 78%, Mw=3,600) of the desired bismaleimide compound (I-1) as a light brown solid.

### Synthesis Example 2 (1-2)

165 g of toluene and 165 g of N-methylpyrrolidone were charged into a 1 L round bottom flask equipped with a thermometer, reflux condenser, Dean-Stark apparatus, powder inlet, nitrogen inlet, and stirrer. Next, 26.6 g (0.20 mol) of metaxylenediamine (manufactured by Mitsubishi Gas Chemical Co., Ltd.) and 11.7 g (0.02 mol) of PRIAMINER 1075 (manufactured by Croda Japan Co., Ltd.) were added, followed by the slow addition of 20.9 g (0.22 mol) of methanesulfonic acid to form the salt. The mixture was stirred for approximately 10 minutes to mix, and then 48.2 g (0.11 mol) of 4,4′-(hexafluoroisopropylidene)diphthalic anhydride was slowly added to the stirred mixture. The mixture was heated to reflux for 6 hours to form the amine-terminated diimide. The water produced from this condensation reached the theoretical amount by this time. The reaction mixture was cooled below room temperature, and 25.5 g (0.26 mol) of maleic anhydride was added to the flask. The mixture was refluxed for an additional 8 hours, yielding the expected amount of water. After cooling to room temperature, the organic layer was washed with water (100 ml×5 times) to remove salts and unreacted raw materials, and a varnish of the bismaleimide compound was obtained. The varnish was then dropped into 1,000 g of methanol to perform a reprecipitation process, and the solvent was removed and dried to obtain 72 g (yield 72%, Mw=4,000) of the desired bismaleimide compound (I-2) as a light brown solid.

### Synthesis Example 3 (I-3)

165 g of toluene and 165 g of N-methylpyrrolidone were charged to a 1 L round bottom flask equipped with a thermometer, reflux condenser, Dean-Stark apparatus, powder inlet, nitrogen inlet, and stirrer. 29.7 g (0.22 mol) of metaxylenediamine (Mitsubishi Gas Chemical Co., Ltd.) was then added, followed by the slow addition of 21.0 g (0.22 mol) of methanesulfonic acid to form the salt. After approximately 10 minutes of stirring to mix, 56.8 g (0.11 mol) of 4,4′-bisphenol A dianhydride was slowly added to the stirred mixture. The mixture was heated to reflux for 6 hours to form the amine-terminated diimide. The water produced from this condensation reached the theoretical amount by this time. The reaction mixture was cooled to below room temperature and 25.7 g (0.26 mol) of maleic anhydride was added to the flask. The mixture was refluxed for an additional 8 hours, yielding the expected amount of water. After cooling to room temperature, the organic layer was washed with water (100 ml×5 times) to remove salts and unreacted raw materials, yielding a varnish of the bismaleimide compound. The varnish was then dropped into 1,000 g of methanol to carry out a reprecipitation step, and the solvent was removed and dried to obtain 78 g (yield 80%, Mw=4,500) of the desired bismaleimide compound (I-3) as a light brown solid.

### Synthesis Example 4 (I-4)

150 g of toluene and 150 g of N-methylpyrrolidone were charged to a 1 L round bottom flask equipped with a thermometer, reflux condenser, Dean-Stark apparatus, powder inlet, nitrogen inlet, and stirrer. 43.9 g (0.32 mol) of metaxylenediamine (Mitsubishi Gas Chemical Co., Ltd.) was then added, followed by the slow addition of 31.0 g (0.32 mol) of methanesulfonic acid to form the salt. The mixture was stirred for approximately 10 minutes to mix, and then 36.1 g (0.16 mol) of 1,2,4,5-cyclohexanetetracarboxylic dianhydride was slowly added to the stirred mixture. The mixture was heated to reflux for 6 hours to form the amine-terminated diimide. The water produced from this condensation reached the theoretical amount by this time. The reaction mixture was cooled to below room temperature, and 37.9 g (0.38 mol) of maleic anhydride was added to the flask. The mixture was refluxed for an additional 8 hours, yielding the expected amount of water. After cooling to room temperature, the organic layer was washed with water (100 ml×5 times) to remove salts and unreacted raw materials, yielding a varnish of the bismaleimide compound. The varnish was then dropped into 1,000 g of methanol to carry out a reprecipitation step, and the solvent was removed and dried to obtain 78 g (yield 78%, Mw=3,000) of the desired bismaleimide compound (I-4) as a white solid.

### Synthesis Example 5 (I-5)

150 g of toluene and 150 g of N-methylpyrrolidone were charged to a 1 L round bottom flask equipped with a thermometer, reflux condenser, Dean-Stark apparatus, powder inlet, nitrogen inlet, and stirrer. 41.2 g (0.30 mol) of metaxylenediamine (Mitsubishi Gas Chemical Co., Ltd.) was then added, followed by the slow addition of 29.1 g (0.30 mol) of methanesulfonic acid to form the salt. The mixture was stirred for approximately 10 minutes to mix, and then 40.0 g (0.15 mol) of 5-(2,5-dioxotetrahydrofuryl)-3-methyl-3-cyclohexene-1,2-dicarboxylic dianhydride was slowly added to the stirred mixture. The mixture was heated to reflux for 6 hours to form the amine-terminated diimide. The water produced from this condensation reached the theoretical amount by this time. The reaction mixture was cooled below room temperature, and 35.6 g (0.36 mol) of maleic anhydride was added to the flask. The mixture was refluxed for an additional 8 hours, yielding the expected amount of water. After cooling to room temperature, the organic layer was washed with water (100 ml×5 times) to remove salts and unreacted raw materials, and a varnish of a bismaleimide compound was obtained. The varnish was then dropped into 1,000 g of methanol to perform a reprecipitation process, and the solvent was removed and dried to obtain 75 g (yield 75%, Mw=3,500) of the desired bismaleimide compound (I-5) as a white solid.

### Synthesis Example 6 (I-6)

154 g of toluene and 154 g of N-methylpyrrolidone were charged to a 1 L round bottom flask equipped with a thermometer, reflux condenser, Dean-Stark apparatus, powder inlet, nitrogen inlet, and stirrer. 39.1 g (0.28 mol) of metaxylenediamine (Mitsubishi Gas Chemical Co., Ltd.) was then added, followed by the slow addition of 27.6 g (0.28 mol) of methanesulfonic acid to form the salt. The mixture was stirred for approximately 10 minutes to mix, and then 43.1 g (0.14 mol) of 4-(2,5-dioxotetrahydrofuran-3-yl)-1,2,3,4-tetrahydronaphthalene-1,2-dicarboxylic anhydride was slowly added to the stirred mixture. The mixture was heated to reflux for 6 hours to form the amine-terminated diimide. The water produced from this condensation reached the theoretical amount by this time. The reaction mixture was cooled below room temperature, and 33.8 g (0.34 mol) of maleic anhydride was added to the flask. The mixture was refluxed for an additional 8 hours, yielding the expected amount of water. After cooling to room temperature, the organic layer was washed with water (100 ml×5 times) to remove salts and unreacted raw materials, and a varnish of a bismaleimide compound was obtained. The varnish was then dropped into 1,000 g of methanol to perform a reprecipitation process, and the solvent was removed and dried to obtain 75 g (yield 75%, Mw=3,200) of the desired bismaleimide compound (I-6) as a white solid.

### Comparative Synthesis Example 1 (BMI-1)

A 500 ml round bottom flask equipped with a fluororesin coated stir bar was charged with 110 g toluene and 36 g N-methylpyrrolidone. Next, 90.9 g (0.17 mol) PRIAMINE® 1075 (Croda Japan Co., Ltd.) was added, followed by the slow addition of 16.4 g (0.17 mol) methanesulfonic anhydride to form the salt. The mixture was stirred for approximately 10 minutes to mix, and then 18.6 g (0.08 mol) pyromellitic anhydride was slowly added to the stirred mixture. A Dean-Stark trap and condenser were attached to the flask. The mixture was heated to reflux for 6 hours to form the amine-terminated diimide. The water produced from this condensation reached the theoretical amount by this time. The reaction mixture was cooled to below room temperature and 20.0 g (0.20 mol) maleic anhydride was added to the flask. The mixture was refluxed for an additional 8 hours to obtain the expected amount of water produced. After cooling to room temperature, an additional 200 ml of toluene was added to the flask. The diluted organic layer was then washed with water (100 ml×3 times) to remove salts and unreacted raw materials. The solvent was then removed under vacuum to obtain 102 g (yield 85%, Mw=3,800) of a brown waxy bismaleimide compound.

The bismaleimide compound of Comparative Synthesis Example 1 is readily available from Designer Molecules Inc. under the name “BMI-3000.”

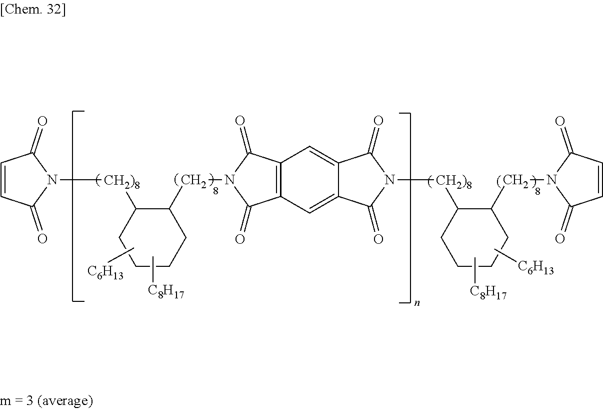

### Comparative Synthesis Example 2 (BMI-2)

A 500 ml round bottom flask equipped with a fluororesin coated stir bar was charged with 110 g toluene and 36 g N-methylpyrrolidone. Next, 85.3 g (0.16 mol) PRIAMINE® 1075 (Croda Japan Co., Ltd.) was added, followed by the slow addition of 15.4 g (0.16 mol) methanesulfonic anhydride to form the salt. The mixture was stirred for approximately 10 minutes to mix, and then 24.8 g (0.08 mol) 4,4′-oxydiphthalic dianhydride was slowly added to the stirred mixture. A Dean-Stark trap and condenser were attached to the flask. The mixture was heated to reflux for 6 hours to form the amine-terminated diimide. The water produced from this condensation reached the theoretical amount by this time. The reaction mixture was cooled to below room temperature and 18.8 g (0.19 mol) maleic anhydride was added to the flask. The mixture was refluxed for an additional 8 hours to obtain the expected amount of water produced. After cooling to room temperature, an additional 200 ml of toluene was added to the flask. The diluted organic layer was then washed with water (100 ml×3 times) to remove salts and unreacted raw materials. The solvent was then removed under vacuum to obtain 106 g of a brown waxy bismaleimide compound (yield 88%, Mw=3,700).

The bismaleimide compound of Comparative Synthesis Example 2 is readily available from Designer Molecules Inc. under the trade name “BMI-1500.”

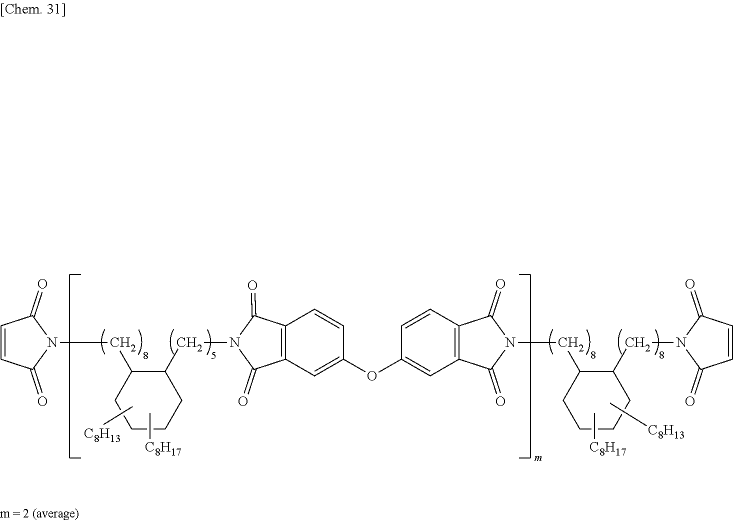

### Comparative Synthesis Example 3 (BMI-3)

The bismaleimide compound (BMI-3) was synthesized by a known method using the method described in Example 1 of JP 2021-123672 A.

A 2L glass four-neck flask equipped with a stirrer, a Dean-Stark tube, a cooling condenser, and a thermometer was added with 37.25 g (0.219 mol) of isophoronediamine, 76.94 g (0.35 mol) of pyromellitic anhydride, and 350 g of toluene, and stirred at 80° C. for 3 hours to synthesize an amic acid. Thereafter, the temperature was raised to 110° C. as it was, and the mixture was stirred for 4 hours while distilling off the by-product water to synthesize a block copolymer.

Then, 116.88 g (0.219 mol) of PRIAMINE (registered trademark) 1075 (manufactured by Croda Japan Co., Ltd.) was added to the flask containing the block copolymer solution cooled to room temperature, and the amic acid was synthesized by stirring at 80° C. for 3 hours. Then, the mixture was heated to 110° C. and stirred for 4 hours while distilling off the by-produced water, synthesizing a diamine at both ends.

The flask containing the diamine at both ends solution was cooled to room temperature, and 18.88 g (0.193 mol) of maleic anhydride was added, and the mixture was heated again and stirred at 80° C. for 3 hours to synthesize an amic acid. The mixture was then heated to 110° C. and stirred for 15 hours while distilling off the by-produced water, and washed five times with 300 g of water to obtain a varnish of a bismaleimide compound. The varnish was then dropped into 3,000 g of isopropyl alcohol (IPA) to perform a reprecipitation process, and the solvent was removed and dried to obtain the desired dark brown solid. (Yield 85%, Mw=8,000)

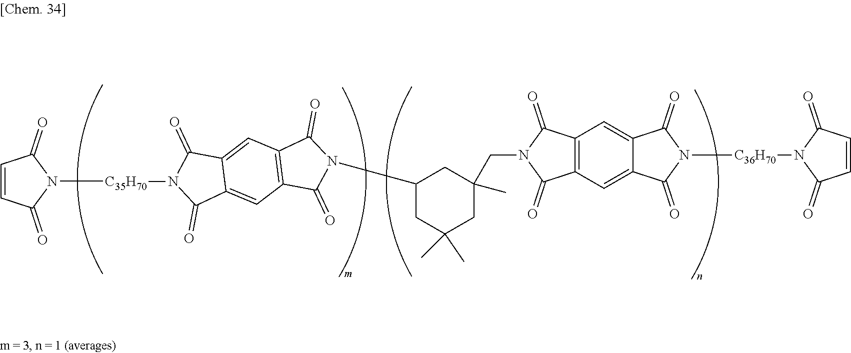

The materials used in this example are as follows.

### [Component (I): Bismaleimide Compound]

I: Bismaleimide compounds shown in Synthesis Examples (I-1) to (I-6) and bismaleimide compounds (BMI-1) to (BMI-3) shown in Comparative Synthesis Examples 1 to 3

### [Component (II); Reaction Accelerator]

(II-1) Dicumyl peroxide (Percumyl D, manufactured by NOF Corp.)
(II-2) Imidazole-based curing accelerator (2E4MZ, manufactured by Shikoku Kasei Corp.)

### [Component (III): Thermosetting Resin]

(III-1): Aromatic maleimide resin represented by the following formula (MIR-3000, manufactured by Nippon Kayaku Co., Ltd.)

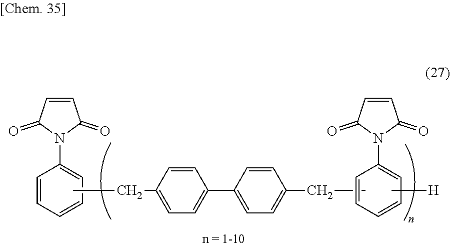

(III-2): Aromatic maleimide resin represented by the following formula (MIR-5000, manufactured by Nippon Kayaku Co., Ltd.)

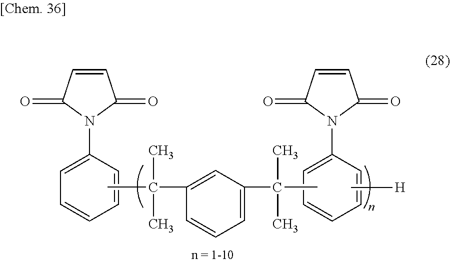

(III-3) Solid bisphenol A type epoxy resin (jER-1001, manufactured by Mitsubishi Chemical Corporation, epoxy equivalent: 475)
(III-4) Terminal styrene-modified polyphenylene ether resin represented by the following formula (OPE-2St-1200, manufactured by Mitsubishi Gas Chemical Company, Inc., number average molecular weight: 1,200)

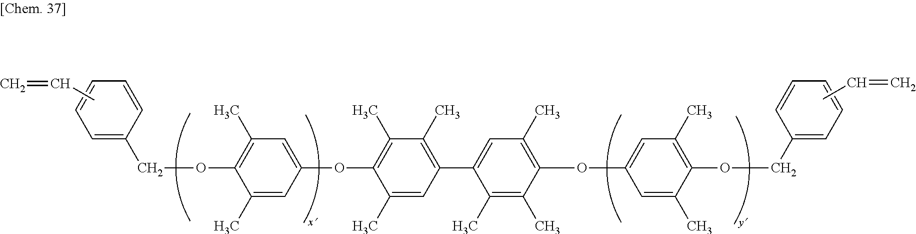

(In the formula, x′ is 0 to 20, y′ is 0 to 20, and x′ and y′ are not both 0 at the same time.)

### Examples 1 to 10 and Comparative Examples 1 to 3

Each component was dissolved and dispersed in anisole in the formulation (parts by mass) shown in Tables 1 to 3, and the non-volatile components were adjusted to 50% by mass to obtain a varnish of a resin composition (varnish 1). The varnish 1 of the resin composition was applied to a PET film having a thickness of 38 μm using a roller coater, and dried at 80° C. for 15 minutes to obtain an uncured resin film having a thickness of 50 μm. In the following evaluation tests, the uncured resin film was used after peeling off the PET film from the uncured resin film prepared on the PET film.

### <Evaluation of Thermosetting Resin Compositions>

The thermosetting resin compositions of Examples 1 to 10 and Comparative Examples 1 to 3 were evaluated as follows. The results are summarized in Tables 1 to 3.

### <Varnish Transparency>

An anisole solution was prepared according to the formulation shown in Tables 1 to 3 to prepare a varnish (varnish 1) with a non-volatile content of 50% by mass. The transparency of the prepared varnish 1 was evaluated under the following two conditions, with a rating of ◯ if both conditions were met and a rating of x if not.
No residual dissolution or turbidity is observed by visual inspection
The direct light transmittance at 740 nm with an optical path length of 1 mm is 50% or more when varnish 1 is placed in a quartz cell and the direct light transmittance is measured using a spectrophotometer U-4100 (manufactured by Hitachi High-Tech Science Corporation).

### <Appearance of Cured Product>

The uncured resin film was cured by curing at 250° C. for 2 hours using a vacuum press, and the appearance of the resulting cured resin film was visually confirmed. A film without uneven curing and with a uniform color throughout was rated as, and a film with uneven curing or separation and with locally different colors was rated as x.

### <Dielectric Properties (Relative Dielectric Constant Dk, Dielectric Loss Tangent Df)>

The uncured resin film was cured by curing at 250° C. for 2 hours using a vacuum press to obtain a cured resin film. The resin film was then cut into test pieces of a length of 60 mm, a width of 2 mm, and a thickness of 0.3 mm, and the dielectric properties (relative dielectric constant Dk, dielectric loss tangent Df) of the test pieces were measured using a cavity resonator perturbation method. The measuring device used was a vector network analyzer ADMSO10c1 manufactured by AET Co., Ltd., and the cavity resonator used was a CP531 (10 GHz band resonator) manufactured by Kanto Electronics Application Development Co., Ltd. The conditions were a frequency of 10 GHz and a measurement temperature of 25° C.

### <Glass Transition Temperature>

The uncured resin film was cured using a vacuum press at 250° C. for 2 hours to obtain a cured resin film.

The dynamic viscoelasticity of the cured bismaleimide product prepared above was measured using a dynamic viscoelasticity measuring device (DMA) (RSA-G2, manufactured by TA Instruments) (frequency 1 Hz, tensile mode, heating rate 3° C./min), and the glass transition temperature was determined from the local maximum value of the loss tangent (tan δ).

### <Copper Foil Adhesive Strength>

First, the uncured resin film was laminated at 80° C. on an E-glass plate measuring 80 mm long×25 mm wide×1 mm thick. Then, a 12 μm-thick ultra-low roughness electrolytic copper foil (CF-T4X-SV (product name), manufactured by Fukuda Metal Foil and Powder Co., Ltd.) was placed on the surface of the glass plate on which the uncured resin film was laminated, and vacuum pressing was performed at a pressure of 1 MPa and a temperature of 250° C. for 120 minutes to obtain a copper-clad laminate bonded to the glass plate via the cured resin film. The glass plate was fixed, and the copper foil was peeled off continuously 5 for 50 mm at a speed of 50 mm per minute by the method described in JIS C6481:1996. The minimum load during this process was taken as the peel strength, which was the adhesive strength between the copper foil and the resin.

TABLE 1

| | | | | Examples | | | | |
|---|---|---|---|---|---|---|---|---|
| | Component | Material | | 1 | 2 | 3 | 4 | 5 |
| (I) | Bismaleimide | Synthesis | I-1 | 80 | | | | |
| | Compounds | Example 1 | | | | | | |
| | | Synthesis | I-2 | | 80 | | | |
| | | Example 2 | | | | | | |
| | | Synthesis | I-3 | | | 80 | | |
| | | Example 3 | | | | | | |
| | | Synthesis | I-4 | | | | 80 | |
| | | Example 4 | | | | | | |
| | | Synthesis | I-5 | | | | | 80 |
| | | Example 5 | | | | | | |
| | | Synthesis | I-6 | | | | | |
| | | Example 6 | | | | | | |
| | | Comparative | BMI-1 | | | | | |
| | | Syunthesis | | | | | | |
| | | Example 1 | | | | | | |
| | | Comparative | BMI-2 | | | | | |
| | | Syunthesis | | | | | | |
| | | Example 2 | | | | | | |
| | | Comparative | BMI-3 | | | | | |
| | | Syunthesis | | | | | | |
| | | Example 3 | | | | | | |
| (II) | Reaction | Percumyl D | II-1 | 1 | 1 | 1 | 1 | 1 |
| | accelerator | 2E4MZ | II-2 | | | | | |
| (III) | Thermosetting | MIR-3000 | III-1 | 20 | 20 | 20 | 20 | 20 |
| | resin | MIR-5000 | III-2 | | | | | |
| | | jER-1001 | III-3 | | | | | |
| | | OPE-2St- | III-4 | | | | | |
| | | 1200 | | | | | | |

| | | | Examples | | | | |
|---|---|---|---|---|---|---|---|
| Evaluation items | | Unit | 1 | 2 | 3 | 4 | 5 |
| Characteristics | Varnish | — | ◯ | ◯ | ◯ | ◯ | ◯ |
| | transparency | | | | | | |
| | Appearance | — | ◯ | ◯ | ◯ | ◯ | ◯ |
| | of Curd | | | | | | |
| | Product | | | | | | |
| | Dielectric | Dk | 2.8 | 2.7 | 2.6 | 2.7 | 2.6 |
| | properties | (10 GHz) | | | | | |
| | | Df | 0.0028 | 0.0019 | 0.0023 | 0.0018 | 0.0021 |
| | | (10 GHz) | | | | | |
| | Heat | Tg (° C.) | 266 | 239 | 234 | 282 | 278 |
| | resistance | | | | | | |
| | Copper foil | kN/m | 1.2 | 1.4 | 1.3 | 1.1 | 1.1 |
| | adhesive | | | | | | |
| | strength | | | | | | |

TABLE 2

| | | | | Examples | | | | |
|---|---|---|---|---|---|---|---|---|
| | Component | Material | | 6 | 7 | 8 | 9 | 10 |
| (I) | Bismaleimide | Synthesis | I-1 | | 80 | 80 | 80 | 100 |
| | Compounds | Example 1 | | | | | | |
| | | Synthesis | I-2 | | | | | |
| | | Example 2 | | | | | | |
| | | Synthesis | I-3 | | | | | |
| | | Example 3 | | | | | | |
| | | Synthesis | I-4 | | | | | |
| | | Example 4 | | | | | | |
| | | Synthesis | I-5 | | | | | |
| | | Example 5 | | | | | | |
| | | Synthesis | I-6 | 80 | | | | |
| | | Example 6 | | | | | | |
| | | Comparative | BMI-1 | | | | | |
| | | Syunthesis | | | | | | |
| | | Example 1 | | | | | | |
| | | Comparative | BMI-2 | | | | | |
| | | Syunthesis | | | | | | |
| | | Example 2 | | | | | | |
| | | Comparative | BMI-3 | | | | | |
| | | Syunthesis | | | | | | |
| | | Example 3 | | | | | | |
| (II) | Reaction | Percumyl D | II-1 | 1 | 1 | | 1 | 1 |
| | accelerator | 2E4MZ | II-2 | | | 1 | | |
| (III) | Thermosetting | MIR-3000 | III-1 | 20 | | | | |
| | resin | MIR-5000 | III-2 | | 20 | | | |
| | | jER-1001 | III-3 | | | 20 | | |
| | | OPE-2St- | III-4 | | | | 20 | |
| | | 1200 | | | | | | |

| | | | Examples | | | | |
|---|---|---|---|---|---|---|---|
| Evaluation items | | Unit | 6 | 7 | 8 | 9 | 10 |
| Characteristics | Varnish | — | ◯ | ◯ | ◯ | ◯ | ◯ |
| | transparency | | | | | | |
| | Appearance | — | ◯ | ◯ | ◯ | ◯ | ◯ |
| | of Curd | | | | | | |
| | Product | | | | | | |
| | Dielectric | Dk | 2.6 | 2.7 | 2.8 | 2.4 | 2.6 |
| | properties | (10 GHz) | | | | | |
| | | Df | 0.0020 | 0.0025 | 0.0033 | 0.0014 | 0.0014 |
| | | (10 GHz) | | | | | |
| | Heat | Tg (° C.) | 249 | 256 | 236 | 310 | 241 |
| | resistance | | | | | | |
| | Copper foil | kN/m | 1.2 | 1.2 | 1.5 | 1.0 | 0.8 |
| | adhesive | | | | | | |
| | strength | | | | | | |

TABLE 3

| | | | | Comparative Examples | | |
|---|---|---|---|---|---|---|
| | Component | Material | | 1 | 2 | 3 |
| (I) | Bismaleimide | Synthesis | I-1 | | | |
| | Compounds | Example 1 | | | | |
| | | Synthesis | I-2 | | | |
| | | Example 2 | | | | |
| | | Synthesis | I-3 | | | |
| | | Example 3 | | | | |
| | | Synthesis | I-4 | | | |
| | | Example 4 | | | | |
| | | Synthesis | I-5 | | | |
| | | Example 5 | | | | |
| | | Synthesis | I-6 | | | |
| | | Example 6 | | | | |
| | | Comparative | BMI-1 | 80 | | |
| | | Syunthesis | | | | |
| | | Example 1 | | | | |
| | | Comparative | BMI-2 | | 80 | |
| | | Syunthesis | | | | |
| | | Example 2 | | | | |
| | | Comparative | BMI-3 | | | 80 |
| | | Syunthesis | | | | |
| | | Example 3 | | | | |
| (II) | Reaction | Percumyl D | II-1 | 1 | 1 | 1 |
| | accelerator | 2E4MZ | II-2 | | | |
| (III) | Thermosetting | MIR-3000 | III-1 | 20 | 20 | 20 |
| | resin | MIR-5000 | III-2 | | | |
| | | jER-1001 | III-3 | | | |
| | | OPE-2St-1200 | III-4 | | | |

| | | | Comparative Examples | | |
|---|---|---|---|---|---|
| Evaluation items | | Unit | 1 | 2 | 3 |
| Characteristics | Varnish | — | X | X | X |
| | transparency | | | | |
| | Appearance of | — | X | X | X |
| | Curd Product | | | | |
| | Dielectric | Dk (10 GHz) | 2.4 | 2.4 | 2.6 |
| | properties | Df (10 GHz) | 0.0035 | 0.0041 | 0.0038 |
| | Heat resistance | Tg (° C.) | 74 | 98 | 165 |
| | Copper foil | kN/m | 0.5 | 0.4 | 0.2 |
| | adhesive | | | | |
| | strength | | | | |

In the thermosetting resin compositions of Examples 1 to 10 in which the bismaleimide compounds of Synthesis Examples 1 to 6 were mixed with a thermosetting resin, the varnish did not remain undissolved or became cloudy, and the resulting cured resin film had a uniform color overall. On the other hand, in the thermosetting resin compositions of Comparative Examples 1 to 3 in which the bismaleimide compounds of Comparative Synthesis Examples 1 to 3 were mixed with a thermosetting resin, the varnish remained undissolved or became cloudy, and the resulting cured resin film had uneven curing or separation. This confirmed that the thermosetting resin composition of the present invention has good compatibility with thermosetting resins.

As is clear from the results shown in Tables 1 to 3, the thermosetting resin composition of the present invention has a high glass transition temperature of the cured product, excellent dielectric properties, excellent adhesion to metal foil, good compatibility with other resins, and cures uniformly without unevenness during curing. Therefore, it has been confirmed that the composition of the present invention is useful for adhesives, substrate materials, primers, coating materials, semiconductor devices, and the like.

This application claims priority based on Japanese Patent Application No. 2023-046184 filed on Mar. 23, 2023.

1. A thermosetting maleimide resin composition comprising:
(I) a bismaleimide compound; and
(II) a reaction accelerator,
wherein the bismaleimide compound (I) is a bismaleimide compound having a cyclic imide bond and obtained by reacting: an aromatic diamine (A) represented by the following formula (1); a tetrabasic acid dianhydride (C); and maleic anhydride: 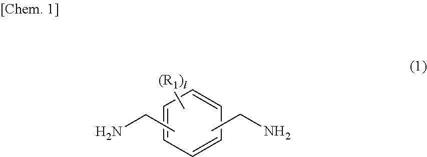
in formula (1),
each R₁ independently represents a hydrogen atom, a linear or branched alkyl group having 1 to 6 carbon atoms, a halogen atom, a hydroxy group, or a linear or branched alkoxy group having 1 to 6 carbon atoms, and
each 1 independently represents an integer of 1 to 4.

2. The thermosetting maleimide resin composition according to claim 1, further comprising:
(III) a thermosetting resin having, as a reactive group capable of reacting with a maleimide group, at least one group selected from: an epoxy group, a maleimide group, a hydroxy group, an acid anhydride group, an alkenyl group, a (meth)acrylic group, a thiol group, a cyano group, a phenol group, an oxetane group, a benzoxazine group, and a carbodiimide group.

3. The thermosetting maleimide resin composition according to claim 1, wherein the bismaleimide compound (I) is obtained by further reacting: a divalent organic diamine (B) having 6 to 200 carbon atoms other than the aromatic diamine (A), in addition to the aromatic diamine (A), the tetrabasic acid dianhydride (C), and the maleic anhydride.

4. The thermosetting maleimide resin composition according to claim 3, wherein the bismaleimide compound (I) is represented by the following general formula (2): 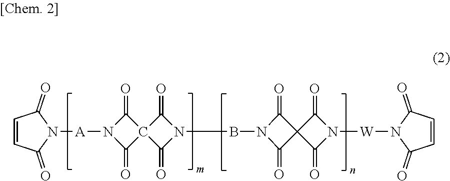
in formula (2), m is 1 to 100, and n is 0 to 100, the order of the repeating units bracketed by m and n is not limited, and the bonding pattern may be alternating, block, or random,
C independently represents a tetravalent organic group containing a cyclic structure,
W is A or B,
B independently represents a divalent hydrocarbon group having 6 to 200 carbon atoms, and
A independently represents a divalent organic group represented by the following formula (3): 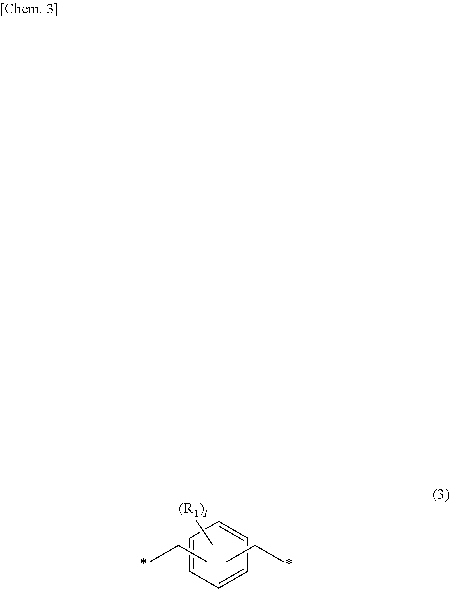
in formula (3), R₁ independently represents a hydrogen atom, a linear or branched alkyl group having 1 to 6 carbon atoms, a halogen atom, a hydroxy group, or a linear or branched alkoxy group having 1 to 6 carbon atoms,
each 1 independently represents an integer of 1 to 4, and
* represents a linking portion with another portion.

5. The thermosetting maleimide resin composition according to claim 1, wherein the tetrabasic acid dianhydride (C) is selected from the group consisting of compounds represented by the following formulas (4) to (12): 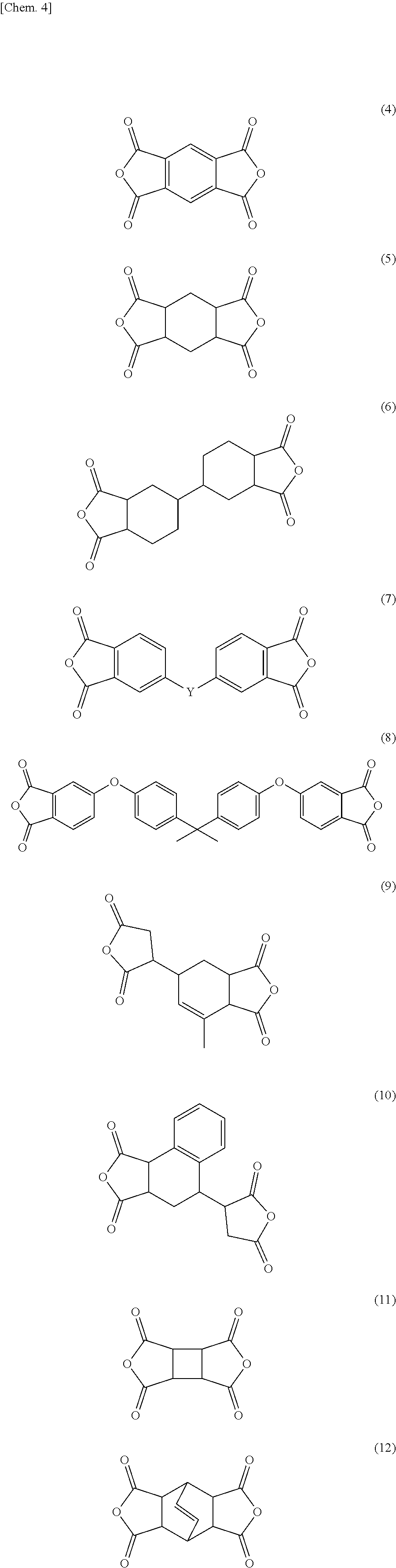
in formula (7), Y represents C(CF₃)₂, SO₂, CO, an oxygen atom, a direct bond, or a divalent linking group represented by the following formula (13): 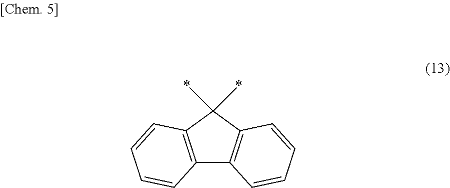
in formula (13), * represents a linking portion to another moiety.

6. The thermosetting maleimide resin composition according to claim 1, wherein the bismaleimide compound (I) is a maleimidized compound of an amine compound represented by the following formula (14): 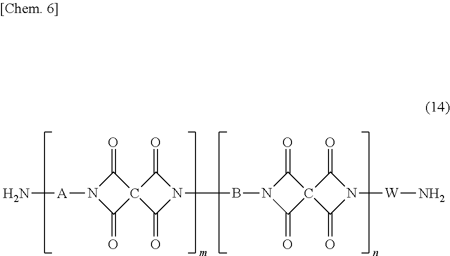
in formula (14),
m is 1 to 100, and n is 0 to 100, the order of the repeating units bracketed by m and n is not limited, and the bonding pattern may be alternating, block, or random,
C independently represents a tetravalent organic group containing a cyclic structure, W is A or B,
B independently represents a divalent hydrocarbon group having 6 to 200 carbon atoms, and
A independently represents a divalent organic group represented by the following formula (3): 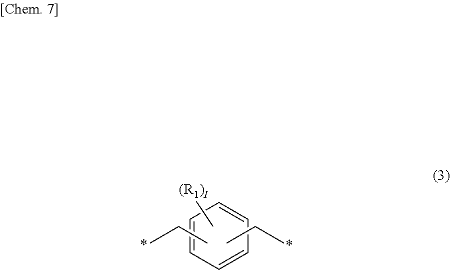
in formula (3),
R₁ independently represents a hydrogen atom, a linear or branched alkyl group having 1 to 6 carbon atoms, a halogen atom, a hydroxy group, or a linear or branched alkoxy group having 1 to 6 carbon atoms,
each 1 independently represents an integer of 1 to 4, and
* represents a linking portion with another portion.

7. The thermosetting maleimide resin composition according to claim 1, wherein the tetrabasic acid dianhydride (C) comprises a bismaleimide compound (I) represented by the following formula (15):

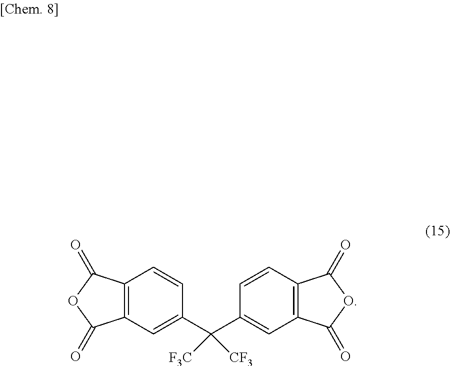 [SMILES: O=C1OC(=O)c2cc(C(c3ccc4c(c3)C(=O)OC4=O)(C(F)(F)F)C(F)(F)F)ccc21]

8. The thermosetting maleimide resin composition according to claim 1, wherein the tetrabasic acid dianhydride (C) comprises a bismaleimide compound (I) represented by the following formula (8):

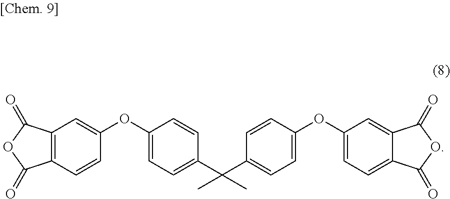 [SMILES: CC(C)(c1ccc(Oc2ccc3c(c2)C(=O)OC3=O)cc1)c1ccc(Oc2ccc3c(c2)C(=O)OC3=O)cc1]

9. The thermosetting maleimide resin composition according to claim 1, wherein the tetrabasic acid dianhydride (C) comprises a bismaleimide compound (I) represented by the following formula (5):

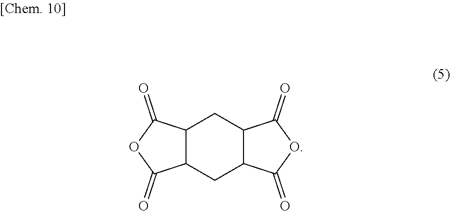 [SMILES: O=C1OC(=O)C2CC3C(=O)OC(=O)C3CC12]

10. The thermosetting maleimide resin composition according to claim 1, wherein the tetrabasic acid dianhydride (C) comprises a bismaleimide compound (I) represented by the following formula (9):

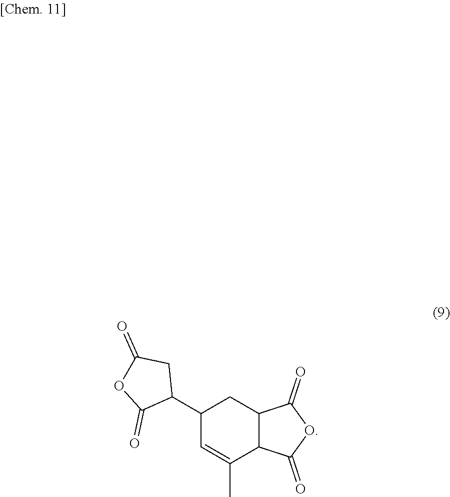 [SMILES: CC1=CC(C2CC(=O)OC2=O)CC2C(=O)OC(=O)C12]

11. The thermosetting maleimide resin composition according to claim 1, wherein the tetrabasic acid dianhydride (C) comprises a bismaleimide compound (I) represented by the following formula (10):

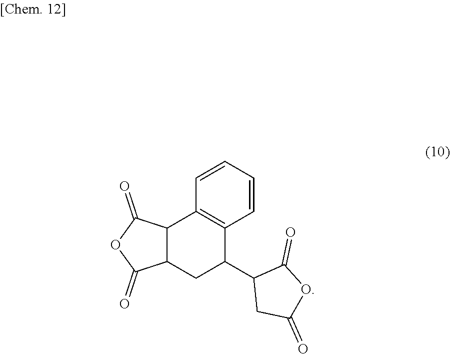 [SMILES: O=C1CC(C2CC3C(=O)OC(=O)C3c3ccccc32)C(=O)O1]

12. The thermosetting resin composition according to claim 2, wherein the (III) thermosetting resin having, as a reactive group capable of reacting with a maleimide group, at least one group selected from an epoxy group, a maleimide group, a hydroxy group, an acid anhydride group, an alkenyl group, a (meth)acrylic group, a thiol group, a cyano group, a phenol group, an oxetane group, a benzoxazine group, and a carbodiimide group is at least one selected from the group consisting of maleimide compounds other than the bismaleimide compound (I), cyanate ester compounds, phenolic resins, epoxy resins, oxetane resins, benzoxazine compounds, carbodiimide compounds, and compounds having an ethylenically unsaturated group.

13. A sheet-like or film-like composition comprising the thermosetting maleimide resin composition according to claim 1.

14. An adhesive composition comprising the thermosetting maleimide resin composition according to claim 1.

15. A primer composition comprising the thermosetting maleimide resin composition according to claim 1.

16. A composition for a substrate, comprising the thermosetting maleimide resin composition according to claim 1.

17. A coating composition comprising the thermosetting maleimide resin composition according to claim 1.

18. A semiconductor device comprising a cured product of the thermosetting maleimide resin composition according to claim 1.
